(19) United States
(12) Patent Application Publication
(10) Pub. No.: US 2025/0385647 A1
(43) Pub. Date: Dec. 18, 2025

(54) TWO-STAGE AMPLIFIER WITH FEEDFORWARD STAGE FOR ENHANCED RECEIVER PERFORMANCE

(71) Applicant: QUALCOMM Incorporated, San Diego, CA (US)

(72) Inventors: Yiming Liu, Milpitas, CA (US); Dayasagar Gaade, Irvine, CA (US); Sean Joel Lyn, Cupertino, CA (US); Shahram Abdollahi-Alibeik, Los Gatos, CA (US)

(21) Appl. No.: 18/745,640

(22) Filed: Jun. 17, 2024

(51) Int. Cl. H03F 1/26; H03F 1/56; H03F 3/45

(52) U.S. Cl. CPC H03F 1/26; H03F 1/56; H03F 3/45179; H03F 2200/222; H03F 2200/294; H03F 2200/451; H03F 2203/45024

(57) ABSTRACT

This disclosure provides systems, methods, and devices for wireless communications that support enhanced two-stage low-noise amplifiers with feedforward circuitry. In a first aspect, a receiver circuit includes a two-stage low-noise amplifier (LNA) configured to amplify a radio frequency (RF) input signal and output a combined amplified RF input signal to a mixer. The two-stage LNA includes a first gain stage configured to amplify the RF input signal and output the amplified RF input signal to a second gain stage of the two-stage LNA and to the mixer via a feedforward path, and includes the second gain stage configured to amplify the amplified RF input signal received from the first gain stage. The two-stage LNA further includes feedforward circuitry in the feedforward path and configured to provide the amplified RF input signal from the first gain stage to the mixer. Other aspects and features are also claimed and described.

### TECHNICAL FIELD

Aspects of the present disclosure relate generally to wireless communication systems, and more particularly, to radio frequency (RF) processing circuitry for wireless communication systems. Some features may enable and provide improved communications, including improved operation of two-stage low-noise amplifiers (LNAs), such as two-stage LNAs with feedforward circuitry.

### INTRODUCTION

Wireless communication networks are widely deployed to provide various communication services such as voice, video, packet data, messaging, broadcast, and the like. These wireless networks may be multiple-access networks capable of supporting multiple users by sharing the available network resources.

A wireless communication network may include several components. These components may include wireless communication devices, such as base stations (or node Bs) that may support communication for a number of user equipments (UEs). A UE may communicate with a base station via downlink and uplink. The downlink (or forward link) refers to the communication link from the base station to the UE, and the uplink (or reverse link) refers to the communication link from the UE to the base station.

A base station may transmit data and control information on a downlink to a UE or may receive data and control information on an uplink from the UE. On the downlink, a transmission from the base station may encounter interference due to transmissions from neighbor base stations or from other wireless radio frequency (RF) transmitters. On the uplink, a transmission from the UE may encounter interference from uplink transmissions of other UEs communicating with the neighbor base stations or from other wireless RF transmitters. This interference may degrade performance on both the downlink and uplink.

As the demand for mobile broadband access continues to increase, the possibilities of interference and congested networks grows with more UEs accessing the long-range wireless communication networks and more short-range wireless systems being deployed in communities. Research and development continue to advance wireless technologies not only to meet the growing demand for mobile broadband access, but to advance and enhance the user experience with mobile communications.

Modern wireless communication networks are sophisticated networks that involve operation on multiple frequencies and multiple frequency ranges. RF signals in different frequencies and ranges may use different components or different configurations of components to support a device operating on these wireless communication networks and maintain high signal integrity and high bandwidth across a range of possible network conditions. The number of supported configurations presents challenges in designing RF systems for the UEs and BSs operating on wireless communication networks.

One such example of a design challenge in supporting multiple configurations is for low-noise amplifiers (LNAs). Two-stage LNAs are sometimes used to offer increased flexibility (such as high gain and low noise) and operation relative to a single-stage LNA across multiple operating modes and input powers. However, in some operating modes and/or input powers, a two-stage LNA may have reduced performance and may not be able to satisfy network operating parameters and/or design constraints. For example, for larger bandwidth applications of next generation wireless communications, such as Wi-Fi 7 and 320 MHz bandwidth operating modes, current two-stage LNA designs may not be able to handle all operating conditions and expected input signal powers. Thus, to support such additional modes, additional or specialized duplicate circuitry, such as a second dedicated off-chip wideband LNA, is needed to handle such additional modes and/or conditions. This leads to duplication of components, which increases area, costs, and power consumption for wireless receivers.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

In one aspect of the disclosure, a receiver circuit includes: a two-stage low-noise amplifier (LNA) configured to amplify a radio frequency (RF) input signal and output a combined amplified RF input signal to a mixer, the two-stage LNA comprising: a first gain stage configured to amplify the RF input signal and output the amplified RF input signal to a second gain stage of the two-stage LNA and to the mixer via a feedforward path; the second gain stage coupled to the first gain stage and configured to amplify the amplified RF input signal received from the first gain stage; and feedforward circuitry in the feedforward path and coupled to the first gain stage and the mixer and coupled in parallel with the second gain stage, the feedforward circuitry configured to provide the amplified RF input signal from the first gain stage to the mixer, wherein the combined amplified RF input signal output by two-stage LNA includes the amplified RF input signal from the feedforward path and the amplified RF input signal from the second gain stage.

In an additional aspect of the disclosure, a method for wireless communication includes: amplifying, by a first gain stage of a two-stage low-noise amplifier (LNA), a radio frequency (RF) input signal to generate an amplified RF input signal; providing, by the first gain stage, the amplified RF input signal to a second gain stage of the two-stage LNA and to a mixer via a feedforward path, the feedforward path having an adjustable impedance; amplifying, by the second gain stage, the amplified RF input signal to generate a second amplified RF input signal; and providing, by the two-stage LNA, a combined amplified RF input signal to the mixer, the combined amplified RF input signal including the amplified RF input signal from the feedforward path and the second amplified RF input signal from the second gain stage.

In another aspect of the disclosure, receiver circuitry includes: two-stage low-noise amplifier (LNA) circuitry including an input coupled to a radio frequency (RF) input and an output coupled to a mixer, the two-stage LNA comprising: first gain stage circuitry including an input coupled to the RF input; second gain stage circuitry coupled to the first gain stage circuitry; and an alternative path coupled to an input of the mixer and to an output of the first gain stage circuitry, the alternative path including adjustable impedance circuitry, wherein the alternative path provides a path to the input of the mixer from the output of the first gain stage circuitry independent of the second gain stage circuitry, wherein the output of the second gain stage circuitry and the output of the alternative path are coupled to the input of the mixer.

In another aspect of the disclosure, receiver circuitry includes: two-stage low-noise amplifier (LNA) circuitry including an input coupled to a radio frequency (RF) input and an output coupled to a mixer, the two-stage LNA comprising: first gain stage circuitry including an input coupled to the RF input; second gain stage circuitry coupled to the first gain stage circuitry, wherein the second gain stage circuitry has a fully-differential configuration, and wherein differential inputs of the second gain stage circuitry are coupled to corresponding differential outputs of the first gain stage circuitry; and first and second alternative paths coupled to inputs of the mixer and to the outputs of the first gain stage circuitry, each alternative path including adjustable impedance circuitry, wherein each alternative path of the alternative paths provides a path to a corresponding input of the inputs of the mixer from a corresponding output of the outputs of the first gain stage circuitry independent of the second gain stage circuitry, wherein the outputs of the second gain stage circuitry and the outputs of the first and second alternative paths are coupled to the inputs of the mixer.

As used herein, a “radio frequency” signal is a signal having a frequency above baseband, which includes, in an example embodiment of a heterodyne receiver, intermediate frequency signals.

As used herein, an “intermediate frequency” signal is an RF signal that has been downconverted from another RF signal to a frequency that is above baseband, such as in an example embodiment of a heterodyne mmWave transceiver that receives a mmWave RF signal and downconverts the mmWave RF signal to a mmWave IF signal that is further processed, such as through further downconversion, to a lower frequency RF signal or a baseband signal.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 is a block diagram illustrating details of an example wireless communication system according to one or more aspects.

FIG. 2 is a block diagram illustrating examples of a base station and a user equipment (UE) according to one or more aspects.

FIG. 3 is a block diagram illustrating a frequency (RF) receiver according to one or more aspects.

FIG. 4 is a block diagram illustrating a wireless transceiver that supports enhanced feedforward operations according to one or more aspects.

FIG. 5 is a diagram illustrating an example of a two-stage low-noise amplifier (LNA) according to one or more aspects.

FIG. 6 is a diagram illustrating an example of a two-stage LNA including a passive feedforward stage that supports enhanced feedforward operations according to one or more aspects.

FIG. 7 is a diagram illustrating another example of a two-stage LNA including a feedforward stage that supports enhanced feedforward operations according to one or more aspects.

FIG. 8 is a diagram illustrating another example of a two-stage LNA including a feedforward stage that supports enhanced feedforward operations according to one or more aspects.

FIGS. 9A-9C are each a diagram illustrating an example of a second stage of a two-stage LNA including a feedforward stage that supports enhanced feedforward operations according to one or more aspects.

FIG. 10 is a flow diagram illustrating an example process that supports enhanced feedforward operations according to one or more aspects.

FIG. 11 is a block diagram of an example UE that supports enhanced feedforward operations in a wireless radio according to one or more aspects of the disclosure.

FIG. 12 is a block diagram of an example base station that supports enhanced feedforward operations in a wireless radio according to one or more aspects of the disclosure.

FIGS. 13A-13C each illustrate a graphs depicting exemplary performance of the two-stage LNAs and stages thereof according to one or more aspects of the disclosure.

Like reference numbers and designations in the various drawings indicate like elements.

### DETAILED DESCRIPTION

The detailed description set forth below, in connection with the appended drawings, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

In various implementations, the techniques and apparatus may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, GSM networks, 5^{th} Generation (5G) or new radio (NR) networks (sometimes referred to as “5G NR” networks, systems, or devices), as well as other communications networks. As described herein, the terms “networks” and “systems” may be used interchangeably.

A CDMA network, for example, may implement a radio technology such as universal terrestrial radio access (UTRA), cdma2000, and the like. UTRA includes wideband-CDMA (W-CDMA) and low chip rate (LCR). CDMA2000 covers IS-2000, IS-95, and IS-856 standards.

A TDMA network may, for example implement a radio technology such as Global System for Mobile Communication (GSM). The 3rd Generation Partnership Project (3GPP) defines standards for the GSM EDGE (enhanced data rates for GSM evolution) radio access network (RAN), also denoted as GERAN. GERAN is the radio component of GSM/EDGE, together with the network that joins the base stations (for example, the Ater and Abis interfaces) and the base station controllers (A interfaces, etc.). The radio access network represents a component of a GSM network, through which phone calls and packet data are routed from and to the public switched telephone network (PSTN) and Internet to and from subscriber handsets, also known as user terminals or user equipments (UEs). A mobile phone operator's network may comprise one or more GERANs, which may be coupled with UTRANs in the case of a UMTS/GSM network. Additionally, an operator network may also include one or more LTE networks, or one or more other networks. The various different network types may use different radio access technologies (RATs) and RANs.

An OFDMA network may implement a radio technology such as evolved UTRA (E-UTRA), Institute of Electrical and Electronics Engineers (IEEE) 802.11, IEEE 802.16, IEEE 802.20, flash-OFDM and the like. UTRA, E-UTRA, and GSM are part of universal mobile telecommunication system (UMTS). In particular, long-term evolution (LTE) is a release of UMTS that uses E-UTRA. UTRA, E-UTRA, GSM, UMTS and LTE are described in documents provided from an organization named “3rd Generation Partnership Project” (3GPP), and cdma2000 is described in documents from an organization named “3rd Generation Partnership Project 2” (3GPP2). These various radio technologies and standards are known or are being developed. For example, the 3GPP is a collaboration between groups of telecommunications associations that aims to define a globally applicable third generation (3G) mobile phone specification. 3GPP LTE is a 3GPP project which was aimed at improving UMTS mobile phone standard. The 3GPP may define specifications for the next generation of mobile networks, mobile systems, and mobile devices. The present disclosure may describe certain aspects with reference to WLAN, LTE, 4G, or 5G NR technologies; however, the description is not intended to be limited to a specific technology or application, and one or more aspects described with reference to one technology may be understood to be applicable to another technology. Additionally, one or more aspects of the present disclosure may be related to shared access to wireless spectrum between networks using different radio access technologies or radio air interfaces.

5G networks contemplate diverse deployments, diverse spectrum, and diverse services and devices that may be implemented using an OFDM-based unified, air interface. To achieve these goals, further enhancements to LTE and LTE-A are considered in addition to development of the new radio technology for 5G NR networks. The 5G NR will be capable of scaling to provide coverage (1) to a massive Internet of things (IoTs) with an ultra-high density (e.g., ˜1 M nodes/km²), ultra-low complexity (e.g., ˜10 s of bits/sec), ultra-low energy (e.g., ˜10+ years of battery life), and deep coverage with the capability to reach challenging locations; (2) including mission-critical control with strong security to safeguard sensitive personal, financial, or classified information, ultra-high reliability (e.g., ˜99.9999% reliability), ultra-low latency (e.g., ˜1 millisecond (ms)), and users with wide ranges of mobility or lack thereof; and (3) with enhanced mobile broadband including extreme high capacity (e.g., ˜10 Tbps/km²), extreme data rates (e.g., multi-Gbps rate, 100+ Mbps user experienced rates), and deep awareness with advanced discovery and optimizations.

Devices, networks, and systems may be configured to communicate via one or more portions of the electromagnetic spectrum. The electromagnetic spectrum is often subdivided, based on frequency or wavelength, into various classes, bands, channels, etc. In 5G NR two initial operating bands have been identified as frequency range designations FR1 (410 MHZ-7.125 GHZ) and FR2 (24.25 GHz-52.6 GHZ). The frequencies between FR1 and FR2 are often referred to as mid-band frequencies. Although a portion of FR1 is greater than 6 GHZ, FR1 is often referred to (interchangeably) as a “sub-6 GHz” band in various documents and articles. A similar nomenclature issue sometimes occurs with regard to FR2, which is often referred to (interchangeably) as a “millimeter wave” (mmWave) band in documents and articles, despite being different from the extremely high frequency (EHF) band (30 GHZ-300 GHz) which is identified by the International Telecommunications Union (ITU) as a “mm Wave” band.

With the above aspects in mind, unless specifically stated otherwise, it should be understood that the term “sub-6 GHz” or the like if used herein may broadly represent frequencies that may be less than 6 GHZ, may be within FR1, or may include mid-band frequencies. Further, unless specifically stated otherwise, it should be understood that the term “mmWave” or the like if used herein may broadly represent frequencies that may include mid-band frequencies, may be within FR2, or may be within the EHF band.

5G NR devices, networks, and systems may be implemented to use optimized OFDM-based waveform features. These features may include scalable numerology and transmission time intervals (TTIs); a common, flexible framework to efficiently multiplex services and features with a dynamic, low-latency time division duplex (TDD) design or frequency division duplex (FDD) design; and advanced wireless technologies, such as massive multiple input, multiple output (MIMO), robust mmWave transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 GHZ FDD or TDD implementations, subcarrier spacing may occur with 15 kHz, for example over 1, 5, 10, 20 MHZ, and the like bandwidth. For other various outdoor and small cell coverage deployments of TDD greater than 3 GHZ, subcarrier spacing may occur with 30 kHz over 80/100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mm Wave components at a TDD of 28 GHz, subcarrier spacing may occur with 120 kHz over a 500 MHz bandwidth.

The scalable numerology of 5G NR facilitates scalable TTI for diverse latency and quality of service (QOS) requirements. For example, shorter TTI may be used for low latency and high reliability, while longer TTI may be used for higher spectral efficiency. The efficient multiplexing of long and short TTIs to allow transmissions to start on symbol boundaries. 5G NR also contemplates a self-contained integrated subframe design with uplink or downlink scheduling information, data, and acknowledgement in the same subframe. The self-contained integrated subframe supports communications in unlicensed or contention-based shared spectrum, adaptive uplink or downlink that may be flexibly configured on a per-cell basis to dynamically switch between uplink and downlink to meet the current traffic needs.

For clarity, certain aspects of the apparatus and techniques may be described below with reference to example 5G NR implementations or in a 5G-centric way, and 5G terminology may be used as illustrative examples in portions of the description below; however, the description is not intended to be limited to 5G applications.

Moreover, it should be understood that, in operation, wireless communication networks adapted according to the concepts herein may operate with any combination of licensed or unlicensed spectrum depending on loading and availability. Accordingly, it will be apparent to a person having ordinary skill in the art that the systems, apparatus and methods described herein may be applied to other communications systems and applications than the particular examples provided.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, implementations or uses may come about via integrated chip implementations or other non-module-component based devices (e.g., end-user devices, vehicles, communication devices, computing devices, industrial equipment, retail devices or purchasing devices, medical devices, AI-enabled devices, etc.). While some examples may or may not be specifically directed to use cases or applications, a wide assortment of applicability of described innovations may occur. Implementations may range from chip-level or modular components to non-modular, non-chip-level implementations and further to aggregated, distributed, or original equipment manufacturer (OEM) devices or systems incorporating one or more described aspects. In some practical settings, devices incorporating described aspects and features may also necessarily include additional components and features for implementation and practice of claimed and described aspects. It is intended that innovations described herein may be practiced in a wide variety of implementations, including both large devices or small devices, chip-level components, multi-component systems (e.g., radio frequency (RF)-chain, communication interface, processor), distributed arrangements, end-user devices, etc. of varying sizes, shapes, and constitution.

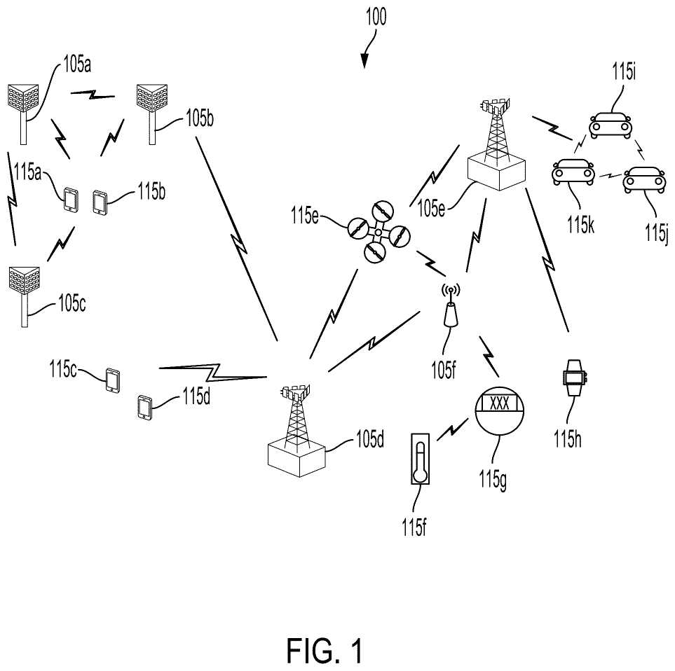

FIG. 1 is a block diagram illustrating details of an example wireless communication system according to one or more aspects. The wireless communication system may include wireless network 100. Wireless network 100 may, for example, include a 5G wireless network. As appreciated by those skilled in the art, components appearing in FIG. 1 are likely to have related counterparts in other network arrangements including, for example, cellular-style network arrangements and non-cellular-style-network arrangements (e.g., device to device or peer to peer or ad hoc network arrangements, etc.).

Wireless network 100 illustrated in FIG. 1 includes a number of base stations 105 and other network entities. A base station may be a station that communicates with the UEs and may also be referred to as an evolved node B (CNB), a next generation eNB (gNB), an access point, and the like. Each base station 105 may provide communication coverage for a particular geographic area. In 3GPP, the term “cell” may refer to this particular geographic coverage area of a base station or a base station subsystem serving the coverage area, depending on the context in which the term is used. In implementations of wireless network 100 herein, base stations 105 may be associated with a same operator or different operators (e.g., wireless network 100 may include a plurality of operator wireless networks). Additionally, in implementations of wireless network 100 herein, base station 105 may provide wireless communications using one or more of the same frequencies (e.g., one or more frequency bands in licensed spectrum, unlicensed spectrum, or a combination thereof) as a neighboring cell. In some examples, an individual base station 105 or UE 115 may be operated by more than one network operating entity. In some other examples, each base station 105 and UE 115 may be operated by a single network operating entity.

A base station may provide communication coverage for a macro cell or a small cell, such as a pico cell or a femto cell, or other types of cell. A macro cell generally covers a relatively large geographic area (e.g., several kilometers in radius) and may allow unrestricted access by UEs with service subscriptions with the network provider. A small cell, such as a pico cell, would generally cover a relatively smaller geographic area and may allow unrestricted access by UEs with service subscriptions with the network provider. A small cell, such as a femto cell, would also generally cover a relatively small geographic area (e.g., a home) and, in addition to unrestricted access, may also provide restricted access by UEs having an association with the femto cell (e.g., UEs in a closed subscriber group (CSG), UEs for users in the home, and the like). A base station for a macro cell may be referred to as a macro base station. A base station for a small cell may be referred to as a small cell base station, a pico base station, a femto base station or a home base station. In the example shown in FIG. 1, base stations 105d and 105e are regular macro base stations, while base stations 105a-105c are macro base stations enabled with one of 3 dimension (3D), full dimension (FD), or massive MIMO. Base stations 105a-105c take advantage of their higher dimension MIMO capabilities to exploit 3D beamforming in both elevation and azimuth beamforming to increase coverage and capacity. Base station 105f is a small cell base station which may be a home node or portable access point. A base station may support one or multiple (e.g., two, three, four, and the like) cells.

Wireless network 100 may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. In some scenarios, networks may be enabled or configured to handle dynamic switching between synchronous or asynchronous operations.

UEs 115 are dispersed throughout the wireless network 100, and each UE may be stationary or mobile. It should be appreciated that, although a mobile apparatus is commonly referred to as a UE in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, a gaming device, an augmented reality device, vehicular component, vehicular device, or vehicular module, or some other suitable terminology. Within the present document, a “mobile” apparatus or UE need not necessarily have a capability to move, and may be stationary. Some non-limiting examples of a mobile apparatus, such as may include implementations of one or more of UEs 115, include a mobile, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A mobile apparatus may additionally be an IoT or “Internet of everything” (IoE) device such as an automotive or other transportation vehicle, a satellite radio, a global positioning system (GPS) device, a global navigation satellite system (GNSS) device, a logistics controller, a drone, a multi-copter, a quad-copter, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, gesture tracking device, medical device, a digital audio player (e.g., MP3 player), a camera, a game console, etc.; and digital home or smart home devices such as a home audio, video, and multimedia device, an appliance, a sensor, a vending machine, intelligent lighting, a home security system, a smart meter, etc. In one aspect, a UE may be a device that includes a Universal Integrated Circuit Card (UICC). In another aspect, a UE may be a device that does not include a UICC. In some aspects, UEs that do not include UICCs may also be referred to as IoE devices. UEs 115a-115d of the implementation illustrated in FIG. 1 are examples of mobile smart phone-type devices accessing wireless network 100. A UE may also be a machine specifically configured for connected communication, including machine type communication (MTC), enhanced MTC (eMTC), narrowband IoT (NB-IOT) and the like. UEs 115e-115k illustrated in FIG. 1 are examples of various machines configured for communication that access wireless network 100.

A mobile apparatus, such as UEs 115, may be able to communicate with any type of the base stations, whether macro base stations, pico base stations, femto base stations, relays, and the like. In FIG. 1, a communication link (represented as a lightning bolt) indicates wireless transmissions between a UE and a serving base station, which is a base station designated to serve the UE on the downlink or uplink, or desired transmission between base stations, and backhaul transmissions between base stations. UEs may operate as base stations or other network nodes in some scenarios. Backhaul communication between base stations of wireless network 100 may occur using wired or wireless communication links.

In operation at wireless network 100, base stations 105a-105c serve UEs 115a and 115b using 3D beamforming and coordinated spatial techniques, such as coordinated multipoint (CoMP) or multi-connectivity. Macro base station 105d performs backhaul communications with base stations 105a-105c, as well as small cell, base station 105f. Macro base station 105d also transmits multicast services which are subscribed to and received by UEs 115c and 115d. Such multicast services may include mobile television or stream video, or may include other services for providing community information, such as weather emergencies or alerts, such as Amber alerts or gray alerts.

Wireless network 100 of implementations supports mission critical communications with ultra-reliable and redundant links for mission critical devices, such UE 115e, which is a drone. Redundant communication links with UE 115e include from macro base stations 105d and 105e, as well as small cell base station 105f. Other machine type devices, such as UE 115f (thermometer), UE 115g (smart meter), and UE 115h (wearable device) may communicate through wireless network 100 either directly with base stations, such as small cell base station 105f, and macro base station 105e, or in multi-hop configurations by communicating with another user device which relays its information to the network, such as UE 115f communicating temperature measurement information to the smart meter, UE 115g, which is then reported to the network through small cell base station 105f. Wireless network 100 may also provide additional network efficiency through dynamic, low-latency TDD communications or low-latency FDD communications, such as in a vehicle-to-vehicle (V2V) mesh network between UEs 115l-115k communicating with macro base station 105c.

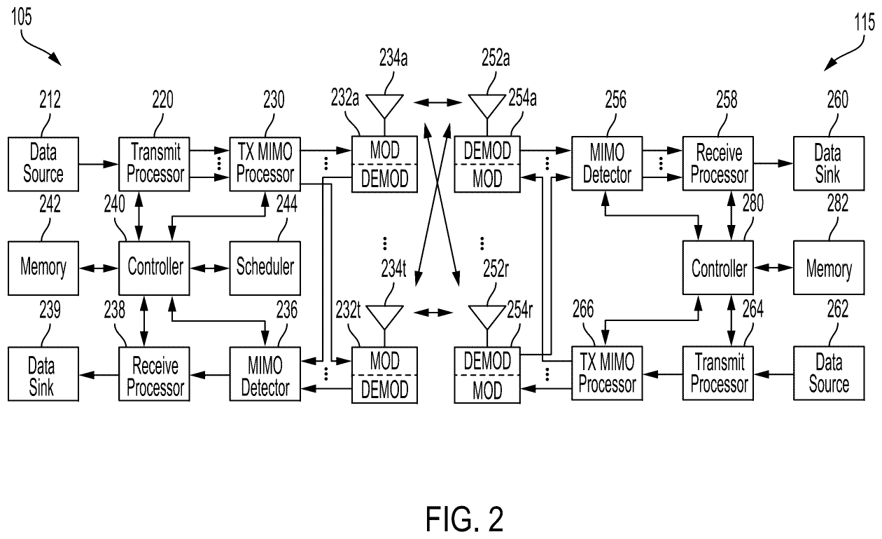

FIG. 2 is a block diagram illustrating examples of base station 105 (e.g., or access point) and UE 115 according to one or more aspects. Base station 105 and UE 115 may be any of the base stations and one of the UEs in FIG. 1. For a restricted association scenario (as mentioned above), base station 105 may be small cell base station 105f in FIG. 1, and UE 115 may be UE 115c or 115d operating in a service area of base station 105f, which in order to access small cell base station 105f, would be included in a list of accessible UEs for small cell base station 105f. Base station 105 may also be a base station of some other type. As shown in FIG. 2, base station 105 may be equipped with antennas 234a through 234t, and UE 115 may be equipped with antennas 252a through 252r for facilitating wireless communications.

At base station 105, transmit processor 220 may receive data from data source 212 and control information from controller 240, such as a processor. The control information may be for a physical broadcast channel (PBCH), a physical control format indicator channel (PCFICH), a physical hybrid-ARQ (automatic repeat request) indicator channel (PHICH), a physical downlink control channel (PDCCH), an enhanced physical downlink control channel (EPDCCH), an MTC physical downlink control channel (MPDCCH), etc. The data may be for a physical downlink shared channel (PDSCH), etc. Additionally, transmit processor 220 may process (e.g., encode and symbol map) the data and control information to obtain data symbols and control symbols, respectively. Transmit processor 220 may also generate reference symbols, e.g., for the primary synchronization signal (PSS) and secondary synchronization signal (SSS), and cell-specific reference signal. Transmit (TX) MIMO processor 230 may perform spatial processing (e.g., precoding) on the data symbols, the control symbols, or the reference symbols, if applicable, and may provide output symbol streams to modulators (MODs) 232a through 232t. For example, spatial processing performed on the data symbols, the control symbols, or the reference symbols may include precoding. Each modulator 232 may process a respective output symbol stream (e.g., for OFDM, etc.) to obtain an output sample stream. Each modulator 232 may additionally or alternatively process (e.g., convert to analog, amplify, filter, and upconvert) the output sample stream to obtain a downlink signal. Downlink signals from modulators 232a through 232t may be transmitted via antennas 234a through 234t, respectively.

At UE 115, antennas 252a through 252r may receive the downlink signals from base station 105 and may provide received signals to demodulators (DEMODs) 254a through 254r, respectively. Each demodulator 254 may condition (e.g., filter, amplify, downconvert, and digitize) a respective received signal to obtain input samples. Each demodulator 254 may further process the input samples (e.g., for OFDM, etc.) to obtain received symbols. MIMO detector 256 may obtain received symbols from demodulators 254a through 254r, perform MIMO detection on the received symbols if applicable, and provide detected symbols. Receive processor 258 may process (e.g., demodulate, deinterleave, and decode) the detected symbols, provide decoded data for UE 115 to data sink 260, and provide decoded control information to controller 280, such as a processor.

On the uplink, at UE 115, transmit processor 264 may receive and process data (e.g., for a physical uplink shared channel (PUSCH)) from data source 262 and control information (e.g., for a physical uplink control channel (PUCCH)) from controller 280. Additionally, transmit processor 264 may also generate reference symbols for a reference signal. The symbols from transmit processor 264 may be precoded by TX MIMO processor 266 if applicable, further processed by modulators 254a through 254r (e.g., for SC-FDM, etc.), and transmitted to base station 105. At base station 105, the uplink signals from UE 115 may be received by antennas 234, processed by demodulators 232, detected by MIMO detector 236 if applicable, and further processed by receive processor 238 to obtain decoded data and control information sent by UE 115. Receive processor 238 may provide the decoded data to data sink 239 and the decoded control information to controller 240.

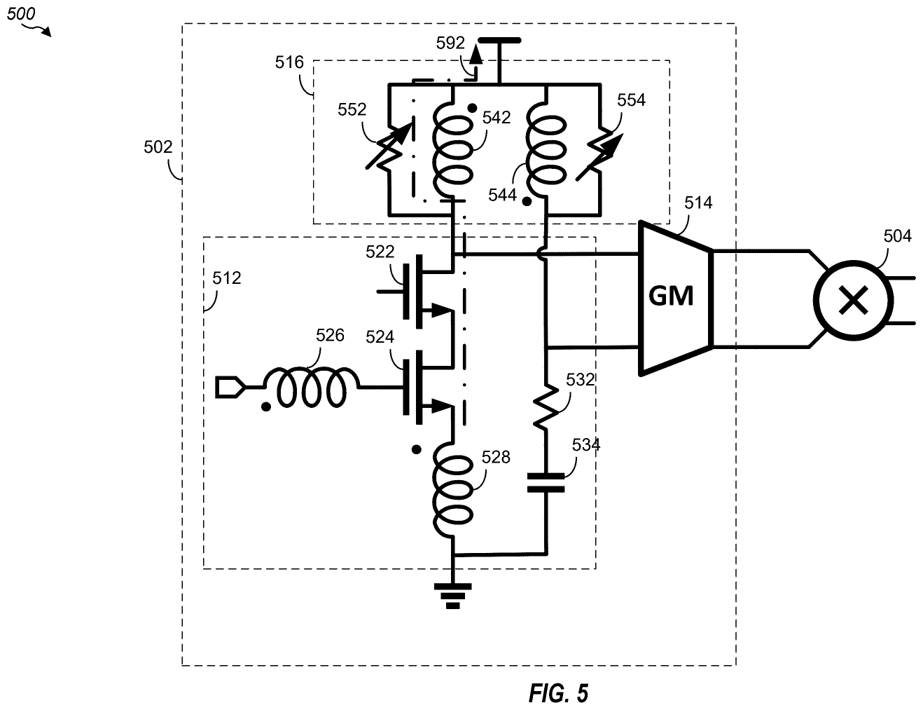

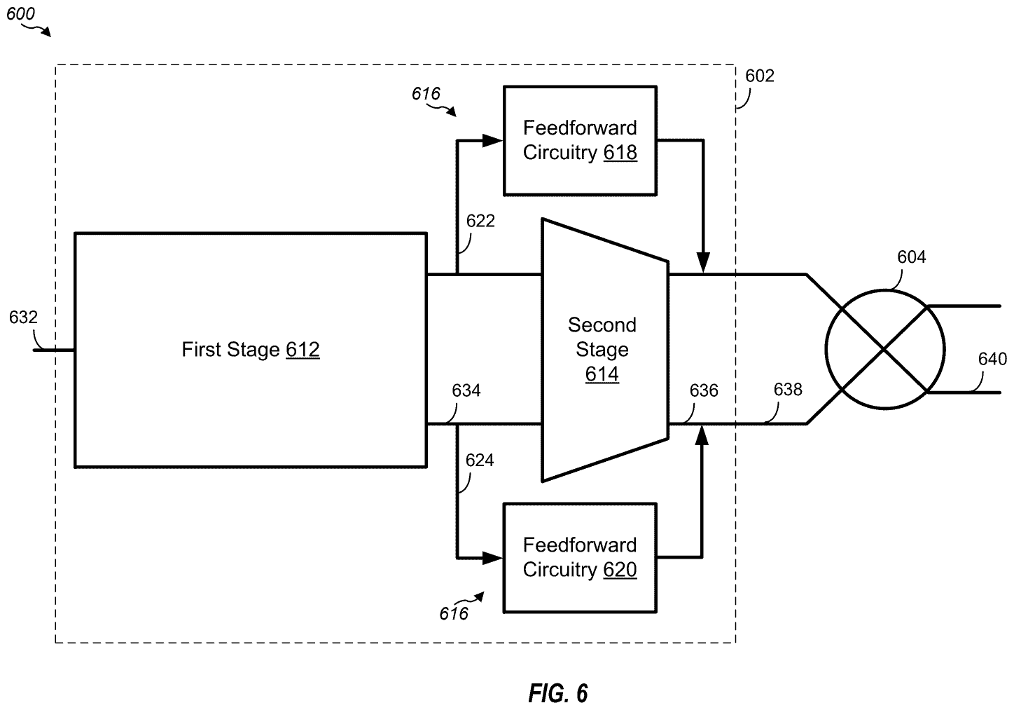

Controllers 240 and 280 may direct the operation at base station 105 and UE 115, respectively. Controller 240 or other processors and modules at base station 105 or controller 280 or other processors and modules at UE 115 may perform or direct the execution of various processes for the techniques described herein, such as to perform or direct the execution illustrated in FIG. 5 or FIG. 6, or other processes for the techniques described herein. Memories 242 and 282 may store data and program codes for base station 105 and UE 115, respectively. Scheduler 244 may schedule UEs for data transmission on the downlink or the uplink.

In some cases, UE 115 and base station 105 may operate in a shared radio frequency spectrum band, which may include licensed or unlicensed (e.g., contention-based) frequency spectrum. In an unlicensed frequency portion of the shared radio frequency spectrum band, UEs 115 or base stations 105 may traditionally perform a medium-sensing procedure to contend for access to the frequency spectrum. For example, UE 115 or base station 105 may perform a listen-before-talk or listen-before-transmitting (LBT) procedure such as a clear channel assessment (CCA) prior to communicating in order to determine whether the shared channel is available. In some implementations, a CCA may include an energy detection procedure to determine whether there are any other active transmissions. For example, a device may infer that a change in a received signal strength indicator (RSSI) of a power meter indicates that a channel is occupied. Specifically, signal power that is concentrated in a certain bandwidth and exceeds a predetermined noise floor may indicate another wireless transmitter. A CCA also may include detection of specific sequences that indicate use of the channel. For example, another device may transmit a specific preamble prior to transmitting a data sequence. In some cases, an LBT procedure may include a wireless node adjusting its own backoff window based on the amount of energy detected on a channel or the acknowledge/negative-acknowledge (ACK/NACK) feedback for its own transmitted packets as a proxy for collisions.

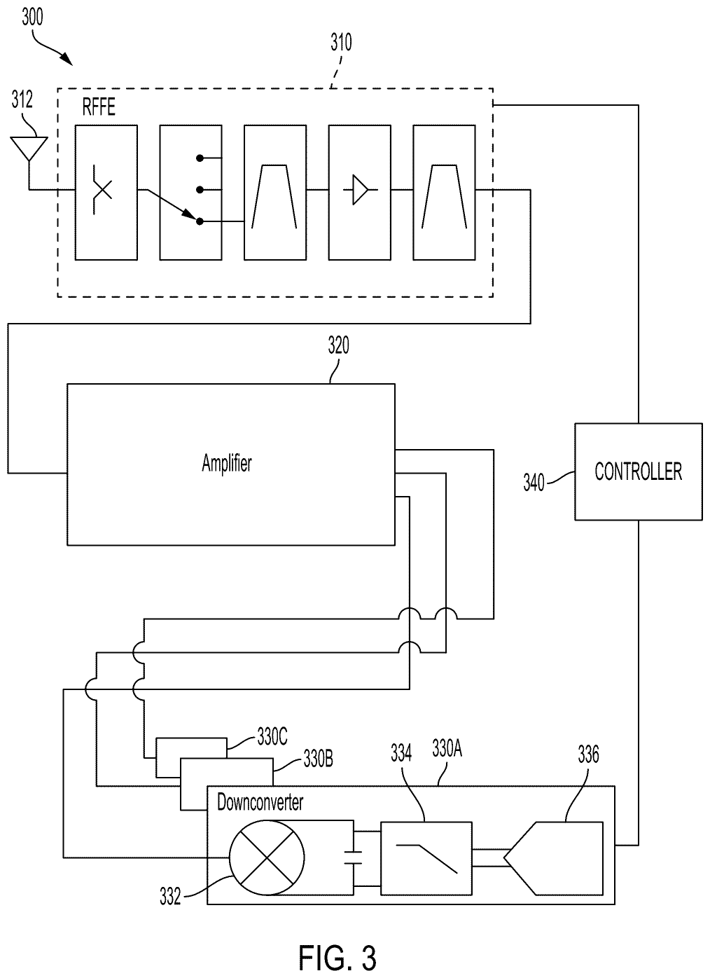

FIG. 3 is a block diagram illustrating a wireless receiver circuit 300 according to one or more aspects. In some embodiments, the receiver circuit 300 may be part of a WiFi transceiver. In some embodiments, the receiver circuit 300 may be part of a converged sub-6 GHz and mmWave radio frequency (RF) transceiver, a sub-6 GHz radio frequency (RF) transceiver, or a mmWave radio frequency (RF) transceiver. In some embodiments, portions or all of the RF transceiver of FIG. 3 may be located in a single integrated circuit (IC) sharing a common substrate. The receiver circuit 300 may include an antenna 312 to receive radio frequency (RF) signals, such as a phase antenna array. The antenna 312 is coupled to an optional RF front-end (RFFE) 310, which may include duplexers, SAW filters, switches, LNAs, and/or other transmit or receive circuits for conditioning signals received from the antenna 312. In some embodiments, the RFFE 310 may include separate circuits for conditioning or otherwise processing sub-6 GHz signals, mmWave signals, satellite signals, and/or other signals. For example, the RFFE 310 may include a first plurality of circuits for conditioning a sub-6 GHz signal for further processing by other circuitry and a second plurality of circuits for conditioning a mmWave RF signal for further processing by other circuitry. The output of the RFFE 310 in this example may be an input RF signal (RF input signal) to other circuitry comprising the conditioned sub-6 GHz signal. The RFFE 310 is coupled to an amplifier 320, such as a low noise amplifier (LNA). The amplifier 320 is coupled to one or more downconverters 330A, 330B, and 330C. Each of the downconverters 330A, 330B, and 330C may include mixers 332, baseband filters (BBFs) 334, and/or analog-to-digital converters (ADCs) 336. The downconverters 330A, 330B, 330C may include one or more harmonic rejection mixers (HRMs). In some embodiments, the amplifier 320 is shared on an IC with one or more of the RFFE 310 and/or the downconverters 330A, 330B, and 330C.

Interference between wireless signals received at antenna 312 and processed through RFFE 310, amplifier 320, and downconverters 330A-C complicates operation of the receiver circuit 300, particularly when processing a large range of potential frequencies.

Aspects herein may apply to carrier aggregation (CA) or similar techniques which involves the combination of one or more carrier RF signals to carry a single data stream. Carrier aggregation (CA) improves the flexibility of the wireless devices and improves network utilization by allowing devices to be assigned different numbers of carriers for different periods of time based, at least in part, on historical, instantaneous, and/or predicted bandwidth use by the wireless device. Thus, when a mobile device needs additional bandwidth, additional carriers may be assigned to that wireless device, and then de-assigned and re-assigned to other mobile devices when bandwidth demands change. As carriers are assigned and de-assigned from a mobile device, the interaction of wireless signals may change. For example, different carriers in CA may be in different bands, and certain bands may have harmonics that overlap and/or otherwise interfere with certain other bands.

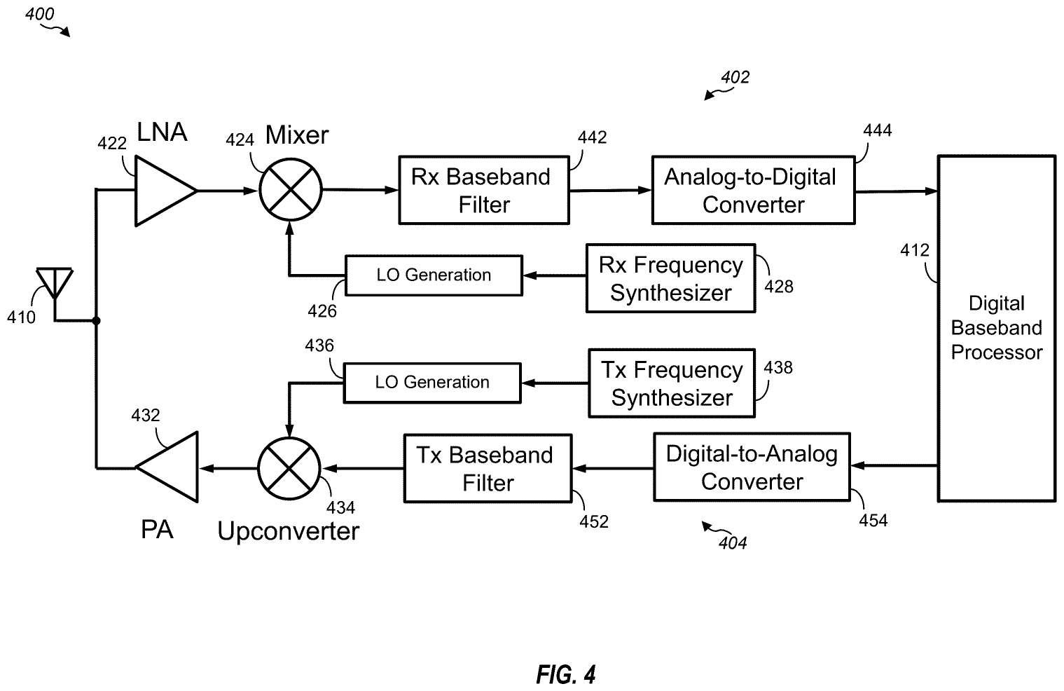

A controller 340 may detect conditions in the RF signal received from the antenna 312 or receive information regarding the carrier configuration from higher levels, such as a MAC layer or network layer. The controller 340 may configure components of the receiver circuit 300 to activate, deactivate, or control portions of the receiver circuit 300 to process an input RF signal. In some embodiments, the controller 340 configures components to reduce power consumption, calibrate components, and/or reduce interference between bands within the receiver circuit 300. In some embodiments, the controller 340 may configure adjustable impedance circuitry, bypass circuity, or both in one or more processing paths within amplifiers of the RFFE 310 and/or amplifier 320, as described further with reference to FIGS. 4-9C.

In high bandwidth applications like Wi-Fi 7, such as high throughput 320 MHZ Bandwidth operations (HT 320), receiver noise may be an impactful metric to receiver performance under certain operating conditions and scenarios. For example, error vector magnitude (EVM) is one measure of performance for receiver quality and signifies constellation mapping errors. In high bandwidth applications, EVM is usually limited by receiver noise for low input power and by linearity at high input power to meet EVM specifications for high bandwidth operations. However, both of a receiver's noise factor (NF), also referred to as noise figure, and its linearity become limiting factors of EVM at moderate/intermediate input power.

Receivers generally have multiple gain stages to achieve high receiver gain across all receiver chains and thereby a low NF. In some such multiple gain stage receivers, a voltage mode low noise amplifier (LNA) stage is typically followed by a transconductance (Gm) stage to achieve both a low NF and a high gain for the entire receiver chain. However, voltage mode LNAs may suffer from poor linearity due to high output swings at some input powers and operating conditions. For example, the poor linearity from the voltage mode LNAs operating at moderate to high input powers degrades the EVM.

For high input powers, the linearity of the receiver may be improved by bypassing the Gm stage, such as by disconnecting the Gm stage and only operating with the voltage mode LNA stage. Bypassing the Gm stage at high input power results in the voltage mode LNA stage operating in a current mode, and the resulting LNA output swing becomes smaller than if the voltage mode LNA was operating in the voltage mode, which improves receiver linearity but degrades NF. However, moderate input power operations still demand both good linearity and good NF, and the current solution of bypassing the Gm stage does not work for moderate/intermediate input powers. Additionally, such multiple gain stage amplifiers may also suffer from signal wasting through a load or LNA output tank of the multiple gain stage amplifier, especially when operating at intermediate input powers, as described further with reference to FIG. 5.

The aspects described herein are directed to improving receiver front end performance at moderate input powers. For example, the receiver front end designs herein improve linearity without sacrificing gain or NF performance, which improves EVM performance and enables satisfaction of EVM specifications at moderate input powers. The receiver front end designs include multiple stage amplifiers which include a feedforward stage.

In the aspects described herein, a feedforward stage for multiple gain stage amplifiers of receiver front end circuitry is described to provide adjustable voltage control into a transconductance (Gm) stage amplifier. The feedforward stage is arranged to provide a path (e.g., an alternative path) around the Gm stage with adjustable resistance to selectively reduce and control the voltage into the Gm stage. The feedforward stage or path may include passive or active circuity to generate the adjustable resistance. Selectively reducing and controlling the voltage into the Gm stage from the first stage (e.g., a voltage mode or hybrid mode stage) enables control of the current and linearity out of the Gm stage and control of the quality of the output into the mixer and of the receiver front end as a whole.

In high input power situations, the Gm stage may not be needed to satisfy the EVM constraints for high bandwidth applications, and thus the Gm stage may be bypassed or shorted, and the input RF signal may be amplified by the first stage in a current mode and flow completely through the feedforward path. In such high power situations, the resistance of the feedforward path may be decreased to zero or to a lowest setting.

In low input power situations, the resistance of the feedforward path may be increased or set to a higher value to prevent the reduction in voltage gain of the first stage LNA. In intermediate input power situations, the resistance of the feedforward path may be selectively controlled to achieve a desired gain and linearity of the two-stage amplifier. To illustrate, by controlling the resistance of the feedforward path, the amount of current provided to the feedforward stage may be increased or decreased to control the amount of current provided to the mixer from the first stage (which is not amplified by the Gm stage). In the intermediate input power situations, the resistance can be adjusted to keep a total gain of the two-stages combined relatively constant and the performance substantially linear. As the resistance decreases, the first stage gain decreases (as it experiences less output impedance in the feedforward path), but the Gm stage gain increases, as more of the first stage output is provided to the Gm stage and not directed to the mixer via the feedforward path (without second amplification). As the resistance increases, the first stage gain increases (as it experiences higher output impedance in the feedforward path), but the Gm stage gain decreases, as more of the first stage output is provided to the Gm stage and not directed to the mixer via the feedforward path.

In some aspects herein, the multiple stage amplifier may include a load or output tank that does not include adjustable resistors or ‘deQ’ resistors. The omission of such resistors reduces or eliminates deQ signal wasting through the adjustable resistor(s) (e.g., deQ resistors) of the load.

The feedforward stage may include one or more passive feedforward networks, one or more active feedforward networks, or a combination thereof. A passive feedforward network may include passive circuit components, and an active feedforward network may include one or more active circuit components (e.g., switch, transistor, etc.). As one illustrative example, the feedforward stage may include an adjustable resistor and a capacitor coupled in series. To illustrate, the adjustable resistor may include or correspond to a variable resistor with a variable or selectable resistance. The adjustable or variable resistor may include or correspond to a passive circuit component or an active circuit component. As illustrative, non-limiting examples, the adjustable or variable resistor may include a potentiometer, a rheostat, a digital resistor, a preset resistor, etc.

As another example, the feedforward network may include a series of selectable non-adjustable resistors and a capacitor coupled in series, and the resistance of the feedforward network and feedforward path may be selected by switching to different resistors with different resistances or by switching in and out different resistors in series to create different resistances. As yet another example, the feedforward network may include one or more active components such as transistors, to control the current through the feedforward path. To illustrate, the feedforward network may include one or more MOSFETs, such as an n-type MOSFET and a p-type MOSFET in series, only an n-type MOSFET, or only a p-type MOSFET. By controlling the MOSFET(s), such as the voltage into a gate thereof, the MOSFET(s) may provide an adjustable amount of current through the feedforward path (through its source and drain) to the mixer.

The adjustable resistance or current through the feedforward path enables the receiver to maintain a total gain of the two-stage amplifier, e.g., the total gain provided to the mixer is linear and constant. The first stage gain corresponds to the first stage output voltage over first stage input voltage, and the total GM gain (Gm gain plus feedforward current) corresponds to the total input current to mixer over the first stage output voltage. The equivalent GM gain corresponds to input current to mixer from the Gm stage over input voltage to the Gm stage. To illustrate, as the resistance of the feedforward path decreases, the first stage gain drops due to the lower impedance of the feedforward path. However, as this resistance of the feedforward path decreases, the Gm gain (including the feedforward path) increases, as compared to higher feedforward path resistances, to maintain the total gain. This inverse relationship enables the two-stage amplifier to produce a constant gain with good linearity and NF across a wider range of input powers and across wide bandwidths. Accordingly, a broader range of communications can be processed with a single two-stage amplifier, which reduces size, cost, complexity, and power consumption.

FIG. 4 is a circuit diagram illustrating a wireless transceiver circuit 400 according to one or more aspects. In some embodiments, portions of the RF transceiver of FIG. 4 may be located in a single integrated circuit (IC) sharing a common substrate, and each portion may be coupled to each other and to a PCB.

The wireless transceiver circuit 400 includes a plurality of receive chains and plurality of transmit chains. In the example of FIG. 4, a single receive chain, first receive chain 402, and a single transmit chain, first transmit chain 404, are illustrated for simplicity. The wireless transceiver circuit 400 may include many more receive chains and/or transmit chains. The additional transmit or receive chains may be grouped together, such as groups of receive chains or groups of transmit chains. For example, in a particular implementation, the wireless transceiver circuit 400 may include 8 groups of 8 receive chains for a total of 64 receive chains. Each group of receive chains may include or correspond to a separate chip or a portion of a chip which is implemented on a PCB in some implementations.

The receive chains of the wireless transceiver circuit 400 may include or correspond to receive chains, feedback receive chains, or a combination thereof. Although the example of FIG. 4 is directed to an example of receive (RX) chains, in other implementations the receive chains may be feedback receive (FBRX) chains and have similar or identical components and/or operations.

Each receive chain may include a corresponding amplifier, mixer, and LO generation circuitry. For example, the first receive chain 402 includes an amplifier 422, a mixer 424 (e.g., downconverter), and LO generation circuitry 426. Each receive chain may be configured to receive a respective RF input signal from a corresponding antenna, such as antenna 410.

Each transmit chain may include a corresponding amplifier, mixer, and LO generation circuitry. For example, the first transmit chain 404 includes an amplifier 432, a mixer 424 (e.g., upconverter), and LO generation circuitry 436. Each transmit chain may be configured to receive multiple types of input signals. For example, each transmit chain may be configured to receive a corresponding respective signal for transmission by a corresponding antenna, such as antenna 410 and/or calibration signals.

The amplifier, amplifier 422, of each receive chain may include or correspond to a low-noise amplifier (LNA) or other type of amplifier in a receive chain. In some implementations, the amplifier may include or correspond to a linear amplifier. The amplifier is configured to amplify received input signals, such as the received RF signals from a corresponding antenna. The amplifier 422 may include or correspond to a two-stage LNA, as described further with reference to FIGS. 5-9C. In some implementations, the two-stage LNA includes a feedforward stage which is able to control an amount of voltage provided to the second stage of the two-stage LNA and a total amount of gain of two-stage LNA, as described further with reference to FIGS. 5-9C. By controlling the voltage to the second stage and/or the amount of current provided through the feedforward path, the two-stage LNA can operate with a substantially constant gain and linearity across a wide range of input powers, even for larger bandwidth applications, such as Wi-Fi 7 320 MHZ.

The amplifier 432 of each transmit chain may include or correspond to a power amplifier or other type of amplifier in a transmit chain. In some implementations, the amplifier may include or correspond to a linear amplifier. The amplifier is configured to amplify received input signals, such as the RF signals to be transmitted by a corresponding antenna.

The mixer, mixers 424 and 434, of each chain may include or correspond to a frequency mixer or multiplier configured to generate a new signal, including or having one or more new frequencies, based on two signals applied to it, such as the difference of the frequencies of the two signals applied to it. Each mixer is configured to generate an output based on a corresponding pair of an input signal and a local oscillator signal. In the example of FIG. 4, the input signal may include or correspond to received signals from a corresponding antenna, and the local oscillator signal may include or correspond to an adjusted (e.g., divided or reduced) local oscillator signal that is received from an external local oscillator (e.g., external phase locked loop (PLL)) and adjusted based on a corresponding on-chip divider. The mixer may include or correspond to a passive mixer or an undriven mixer in some implementations. Additionally, or alternatively, the mixer may include or correspond to an unbalanced mixer, a single-balanced mixer, or a double-balanced mixer. The mixer may include one or more circuit components such as transistors or diodes to generate the output.

The LO generation circuitry, LO generation circuitry 426 and 436, of each chain may include or correspond to circuitry configured to generate a LO signal based on a synchronization signal or clock signal from signal generation circuitry, such as the frequency synthesizers 428 or 438.

The frequency synthesizers 428 and 438 of each chain may include or correspond to synchronization signal or clock signal generation circuitry. For example, the frequency synthesizers 428 and 438 may be configured to generate a signal with a particular frequency for LO processing and LO signal generation for mixing or upconverting. The LO signal may enable further baseband processing (e.g., baseband filtering) for receiving RF signals and generation of RF signals for transmission. With this architecture, each chain receive and/or transmit chain may have a corresponding LO generation circuit and be capable of performance in many modes.

The receiver baseband filter 442 of each receive chain may include or correspond to filter circuitry configured to filter out signals outside of baseband frequencies generated by the mixer 424.

The ADC 444 of each receive chain may include or correspond to ADC circuitry configured to convert a received analog signal back to its digital signal, sequence of bits, it was created from. For example, a signal with varying frequency and/or amplitude may be converted to a sequence of bits with bit values corresponding to the frequency and/or amplitude.

The transmit baseband filter 452 of each of each transmit chain may include or correspond to transmit baseband filter circuitry configured to filter the converted analog signal for mixing and transmission by the antenna 410.

The DAC 454 of each transmit chain may include or correspond to DAC circuitry configured to convert a digital signal, e.g., a sequence of bits, to an analog signal, such as a signal with varying frequency and/or amplitude which indicates or corresponds to bit values of the sequence.

The wireless transceiver circuit 400 includes one or more antennas, such as antenna 410, and a digital baseband processor 412. The antenna 410 is configured to transmit and receive RF energy corresponding to RF signals. The digital baseband processor 412 includes or corresponds digital baseband processing circuitry and is configured to process data for transmission and to process data from received RF signals.

The digital baseband processor 412 is configured to receive outputs from the receive chains and process the output of the receive chains. For example, the digital baseband processor 412 is configured to receive a corresponding digital output (e.g., a sequence of zeros and ones corresponding to the filtered analog signal) from each receive chain of the plurality of receive chains 402-408 and to perform baseband processing on the output.

Although the digital baseband processor 412 is coupled to the output of the respective ADC of each receive chain and configured to receive a respective output of each receive chain in FIG. 4, the output of receive chain may bypass the digital baseband processor 412 in some implementations, such as by the use of switches, traces, or other bypass circuitry. For example, during calibration, the output of each receive chain may physically bypass the digital baseband processor 412 and be directed to RF calibration processing or may pass through the digital baseband processor 412 without the digital baseband processor 412 processing the signal.

Additionally, the digital baseband processor 412 is configured to generate signals for wireless transmission. For example, the digital baseband processor 412 is configured to receive data and generate one or more sequences of bits for conversion to an analog signal based on and/or indicating the data.

FIG. 5 is a circuit diagram illustrating a wireless receiver circuit 500 according to one or more aspects. In some embodiments, portions of the RF receiver (or transceiver) of FIG. 5 may be located in a single integrated circuit (IC) sharing a common substrate, and each portion may be coupled to each other and to a PCB.

The wireless receiver circuit 500 includes or corresponds to a portion of a wireless receiver circuit, such as an LNA and a mixer of a particular receive chain of a wireless receiver. The wireless receiver circuit 500 includes a two-stage LNA 502 and a mixer 504. In FIG. 5, one exemplary receive chain is illustrated for simplicity. Each receive chain of the wireless receiver circuit 500 may include a two-stage LNA 502 and a mixer 504. The wireless receiver circuit 500 may include many more receive chains and groups of receive chains. For example, in a particular implementation, the wireless receiver circuit 500 may include 8 groups of 8 receive chains for a total of 64 receive chains. Each group of receive chains may include or correspond to a separate chip or portion of chip which is implemented on a PCB.

The two-stage LNA 502 may include or correspond to the amplifier 320 of FIG. 3 or the amplifier 422 of FIG. 4. The two-stage LNA 502 includes a first gain stage 512, a second gain stage 514, a load 516. The two-stage LNA 502 is configured to receive an RF input signal, to amplify the RF input signal to generate an amplified RF input signal, and to provide the amplified RF input signal to the mixer 504. The amplified RF input signal output by the two-stage LNA 502 corresponds to twice amplified RF input signal as each stage of the two-stage LNA amplifier the signal received. The load 516 may generate a load used by one or more stages of the two-stage LNA 502.

The first gain stage 512 includes first gain or amplification circuity configured to amplify the RF input signal received at the first gain stage 512 from an antenna via RFFE circuity. The first gain stage 512 may include or correspond to a cascode amplifier including multiple transistors coupled in series (or a cascading fashion). The first gain stage 512 may include one or more other circuit components, such as one or more other passive circuit components such as inductors, capacitors, or resistors.

As illustrated in the example of FIG. 5, the first gain stage 512 includes a first transistor 522, a second transistor 524, a first inductor 526, a second inductor 528, a capacitor 534 and a resistor 532.

The first and second transistors 522 and 524 may include or correspond to cascode transistors and are coupled in series. As illustrated in the example of FIG. 5, the first and second transistors 522 and 524 are n-type MOSFETS (NMOS) coupled in series (e.g., drain to source) where a gate of the second transistor 524 is coupled to an RF input, via the first inductor 526 and configured to receive an RF input signal. The first transistor 522, such as drain thereof, is coupled to an output of the load 516 and an input of the second gain stage 514.

The first inductor 526 is configured to receive the RF input signal and provide the RF input signal to the gate of the second transistor 524. The second inductor 526 is coupled to the second transistor 524, such as a source thereof, to circuit ground, and to capacitor 534. Capacitor 534 is coupled to resistor 532, and resistor 532 is coupled to one output of the load 516 and an input of the second gain stage 514.

The second gain stage 514 includes second gain or amplification circuity configured to amplify a received amplified RF input signal received from the first gain stage 512. The second gain stage 514 may include or correspond to transconductance (Gm) gain stage. For example, the second gain stage 514 may include a transconductance amplifier. As illustrated in the example of FIG. 5, the second gain stage 514 includes a fully-differential transconductance amplifier, having a differential set of inputs and outputs.

The load 516 includes or corresponds to a load for the two-stage LNA 502, including the first gain stage 512 thereof. The load 516 may include or correspond to an output tank and include circuity configured to generate a load for RF signal amplification. The load 516 includes one or more inductors and one or more adjustable resistors.

As illustrated in the example of FIG. 5, the load 516 includes a first inductor 542, a second inductor 544, a first adjustable resistor 552 and a second adjustable resistor 554. The adjustable resistors 552 and 554 are configured to have an adjustable, configurable, or otherwise selectable resistance. The adjustable resistors 552 and 554 may each include a single component or device which is capable of having or generating different resistances based on signals and/or conditions applied to it in some implementations. In other implementations, the adjustable resistors 552 and 554 may each include or correspond to multiple components which are capable of generating different resistances. For example, the adjustable resistors 552 and 554 may include a network of switchable resistors coupled in series and/or parallel where a controller, such as controller 340 of FIG. 3, may be configured to activate the switches to switch states to connect or activate a different combinations of resistors to generate different resistances.

In the example of FIG. 5, the inductors 542 and 544 are coupled in parallel with each other and with the adjustable resistors 552 and 554. Specifically, the inductors 542 and 544 are coupled with an opposing orientation (e.g., a subtractive mode coupled with their windings and respective inputs and outputs in opposite directions). To illustrate, the orientation of the inductors are opposed 542 and 544 with the first inductor 542 having an output towards the circuit source (upwards in FIG. 5) and the second inductor 544 having an output towards the first gain stage 512 and the circuit drain/ground (downwards in FIG. 5).

Each inductor of the inductors 542 and 544 has a corresponding adjustable resistor coupled in parallel with the inductor and configured to provide a sort of alternative path for the LNA tank. The adjustable resistors 552 and 554 may include or correspond to degeneration resistors, referred to as “deQ” resistors, and may be configured to dissipate power and decrease a Q factor of the circuit in some states or operational modes (e.g., low or high power input signal operational modes). However, at moderate or intermediate input signal operational modes, the circuit may experience unwanted signal wasting through one or more of the adjustable resistors 552 and 554, such as the first adjustable resistor 552.

The mixer 504 may include or correspond to the mixer 332 of FIG. 3 or the mixer 424 of FIG. 4. The mixer 504 may include or correspond to a frequency mixer or multiplier configured to generate a new signal, including or having one or more new frequencies, based on two signals applied to it, such as the difference of the frequencies of the two signals applied to it. For example, the mixer 504 is configured to generate an output based on an input signal and a local oscillator (LO) signal. In some implementations, the mixer 504 may include or correspond to a passive mixer. Additionally, the mixer 504 may be viewed as active or driven when combined with the second gain stage 514. The mixer 504 may include or correspond to an unbalanced mixer, a single-balanced mixer, or a double-balanced mixer. The mixer 504 may include one or more circuit components, such as transistors or diodes to generate the output.

In FIG. 5, the mixer 504 is configured to receive an amplified RF input signal (which has been twice amplified, once by each stage of the two-stage LNA 502) from the second gain stage 514 of the two-stage LNA 502 and to receive an LO signal from LO circuitry (not shown in FIG. 5), such as the LO generation circuitry of FIG. 4. The mixer 504 is configured to mix the received signals and generate a mixed signal based on the inputs, that is an output signal. The output signal is provided to baseband processing circuitry, such as a baseband filter, not shown in FIG. 5 for simplicity. The baseband processing circuitry may include or correspond to the BBF 334 as in FIG. 3 or the digital baseband processor 412 as in FIG. 4.

In some implementations, the baseband processing circuitry includes a transinductance amplifier (TIA) configured to amplify the output or baseband signal, such as to convert current to voltage.

The wireless receiver circuit 500 may also be coupled to an antenna, such as antenna 410 of FIG. 4, and configured to receive RF energy received by the antenna. For example, mixers of the wireless receiver circuit 500 may be configured to receive amplified RF energy from the antenna (e.g., an RF input as shown in FIG. 5).

During operation, an RF signal is received by the antenna and provided to the receive chain of the wireless receiver circuit 500 illustrated in FIG. 5. To process the received RF signal at the mixer 504, the received RF signal may need to be amplified before being mixed and downconverted to baseband frequencies for processing by a baseband processor. The two-stage LNA 502 receives the RF signal at the gate of the second transistor 524 via the first inductor 526. The RF signal applied to the gate of the second transistor 524 controls the flow of current through the second transistor 524 based on a load generated by the load 516. The application of the RF signal to the gate of the second transistor 524 amplifies the RF signal.

The amplified RF signal is provided to the second gain stage 514, the transconductance or Gm stage. The second gain stage 514 amplifies the amplified RF signal and provides the amplified RF signal (twice amplified RF signal) to the mixer 504.

To process the received RF signal at the mixer 504, an LO signal is also generated and provided to the mixer 504 by LO circuitry, as known in the art. The mixer 504 processes (e.g., mixes) the two received signals to generate a processed, mixed, or baseband signal for further/baseband processing by the baseband processor.

In some operational modes, such as at low input signal power modes, the amplified RF input signal generated by the two-stage LNA 502 may satisfy certain operating constraints of networks, such as linearity, NF, input third-order intercept power (IIP3), etc., and both stages are needed to meet gain or input power requirements.

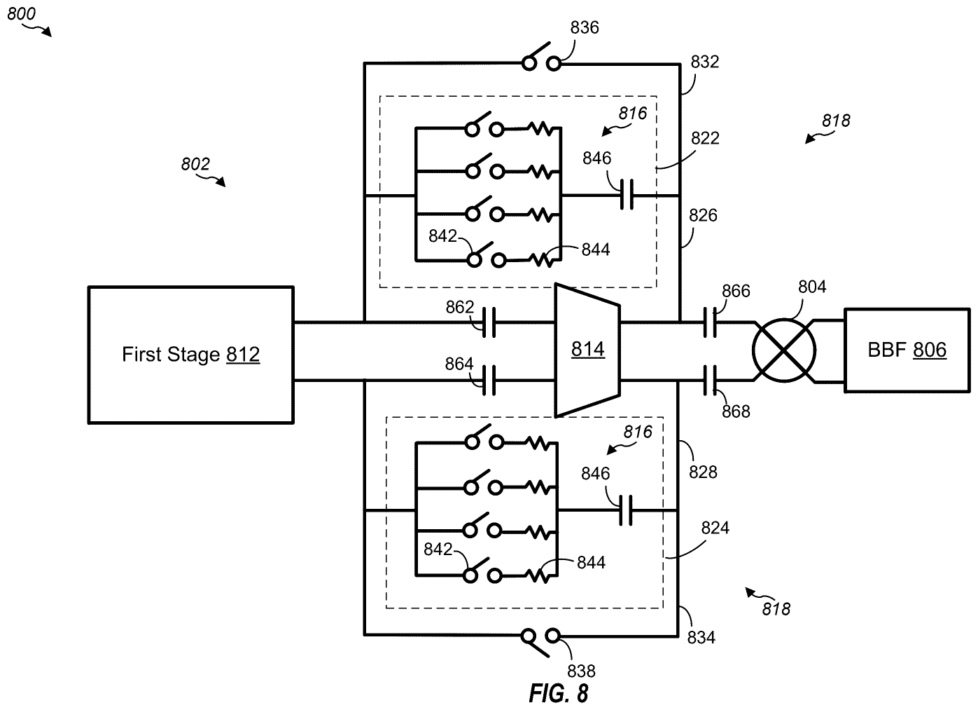

In some operational modes, such as at high input signal power modes, the second gain stage 514 of the two-stage LNA 502 may not be needed or may cause non-linearity, and thus, the second gain stage 514, may be bypassed by bypass circuity, such as described further with reference to FIG. 8. For example, the gain of the first gain stage 512 may be enough for baseband processing and/or the gain from the second gain stage 514 may cause issues with meeting certain constraints of networks, such as linearity, NF, IIP3, etc.

In some operational modes, such as moderate or intermediate input signal power modes, operation of the two-stage LNA 502 may cause unwanted signal wasting through one or more of the adjustable resistors 552 and 554, such as the first adjustable resistor 552, which may reduce performance of the two-stage LNA 502, it may degrade linearity, NF, and/or IIP3. An example of signal wasting through the first adjustable resistor 552 is illustrated by the dashed and dotted line 592.

Additionally, operation of the second gain stage 514 may be required to meet certain gain or power requirements or design constraints for the wireless receiver circuit 500 at moderate or intermediate input powers. However, operations of the second gain stage 514 may cause the output amplified RF signal to not be in conformance with design specifications and/or network operating parameters. Thus, the design of wireless receiver circuit 500 may not be suitable for intermediate/moderate power modes. As an illustrative example, input power to the receiver is −70 dBm for low power modes, −36 dBm for intermediate/moderate power modes, and −20 dBm for high power modes.

FIG. 6 is a circuit diagram illustrating a wireless receiver circuit 600 according to one or more aspects. The wireless receiver circuit 600 may include or correspond to a wireless receiver circuit for wideband Wi-Fi operations, such as HT 320 operations of Wi-Fi 7. In some embodiments, the wireless receiver circuit 600 may be part of a sub-6 GHz radio frequency (RF) transceiver, a converged sub-6 GHz and mmWave radio frequency (RF) transceiver, or a mmWave radio frequency (RF) transceiver. In some embodiments, portions of the RF receiver (or transceiver) of FIG. 6 may be located in a single integrated circuit (IC) sharing a common substrate, and each portion may be coupled to each other and to a PCB.

The wireless receiver circuit 600 includes or corresponds to a portion of a wireless receiver circuit, such as an LNA and a mixer of a particular receive chain of a wireless receiver. The wireless receiver circuit 600 includes a plurality of receive chains, and in FIG. 6, components of one receive chain are illustrated for simplicity.

The wireless receiver circuit 600 includes a two-stage LNA 602 and a mixer 604. In FIG. 6, one exemplary receive chain is illustrated for simplicity. Each receive chain of the wireless receiver circuit 600 may include a two-stage LNA 602 and a mixer 604. The wireless receiver circuit 600 may include many more receive chains and groups of receive chains. For example, in a particular implementation, the wireless receiver circuit 600 may include 8 groups of 8 receive chains for a total of 64 receive chains. Each group of receive chains may include or correspond to a separate chip or a portion of a chip which is implemented on a PCB.

The two-stage LNA 602 may include or correspond to the amplifier 320 of FIG. 3, the amplifier 422 of FIG. 4, or the two-stage LNA 502 of FIG. 5. The two-stage LNA 602 includes a first gain stage 612, a second gain stage 614, and a feedforward stage 616. The two-stage LNA 602 is configured to receive an RF input signal 632, to amplify the RF input signal 632 to generate an amplified RF input signal 634, and to provide the amplified RF input signal 634 to the mixer 604 via the second gain stage 614, the feedforward stage 616, or both.

Depending on the input power of the RF input signal 632, and the corresponding power of the amplified RF input signal 634 from the first gain stage 612, the amplified RF input signal 634 from the first gain stage 612 may be routed or provided to the mixer 604 via the second gain stage 614 alone, the feedforward stage 616 alone, or both. For example, a portion (first portion) of the current of the amplified RF input signal 634 from the first gain stage 612 may be provided to the mixer 604 via the second gain stage 614, and a portion (second portion) of the current of the amplified RF input signal 634 from the first gain stage 612 may be provided to the mixer 604 via the feedforward stage 616 without second amplification. The portion (first portion) of the current of the amplified RF input signal 634 from the first gain stage 612 that is provided to the mixer 604 via the second gain stage 614 is amplified a second time by the second gain stage 614. Thus, the amplified RF input signal received by the mixer 604 may correspond to a combined amplified RF input signal 638 including current from a twice amplified RF input signal 636 from the second gain stage 614 and current from the amplified RF input signal 634 from the feedforward stage 616.

The first gain stage 612 is coupled to an RF input, to the second gain stage 614, and to the feedforward stage 616. The first gain stage 612 is coupled to the mixer 604 via the second gain stage 614 and the feedforward stage 616. For example, outputs (e.g., differential outputs) of the first gain stage 612 are coupled to inputs of the second gain stage 614 and to inputs of the feedforward stage 616.

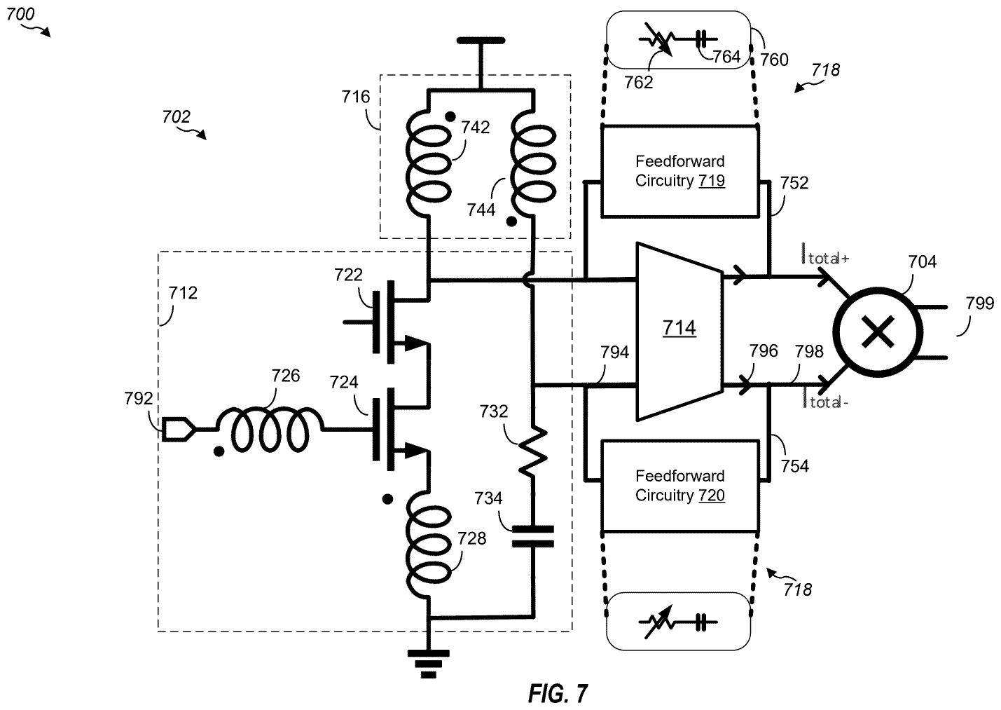

The first gain stage 612 includes first gain or amplification circuity configured to amplify the RF input signal 632 received at the first gain stage 612 from an antenna via RFFE circuity. The first gain stage 612 may include or correspond to a cascode amplifier or cascade amplification circuitry including multiple transistors coupled in series (or a cascading fashion). The first gain stage 612 may include one or more other circuit components, such as one or more other passive circuit components such as inductors, capacitors, or resistors. The first gain stage 612 may include or correspond to a voltage gain stage and may be configured to operate in a voltage gain mode. An example of first gain or amplification circuity of the first gain stage 612 is further described with reference to FIG. 7.

The second gain stage 614 is coupled to first gain stage 612, the feedforward stage 616, and the mixer 604. For example, inputs (e.g., differential inputs) of the second gain stage 614 are coupled to outputs of the first gain stage 612 and to inputs of the feedforward stage 616, and outputs (e.g., differential outputs) of the second gain stage 614 are coupled to inputs of the mixer 604.

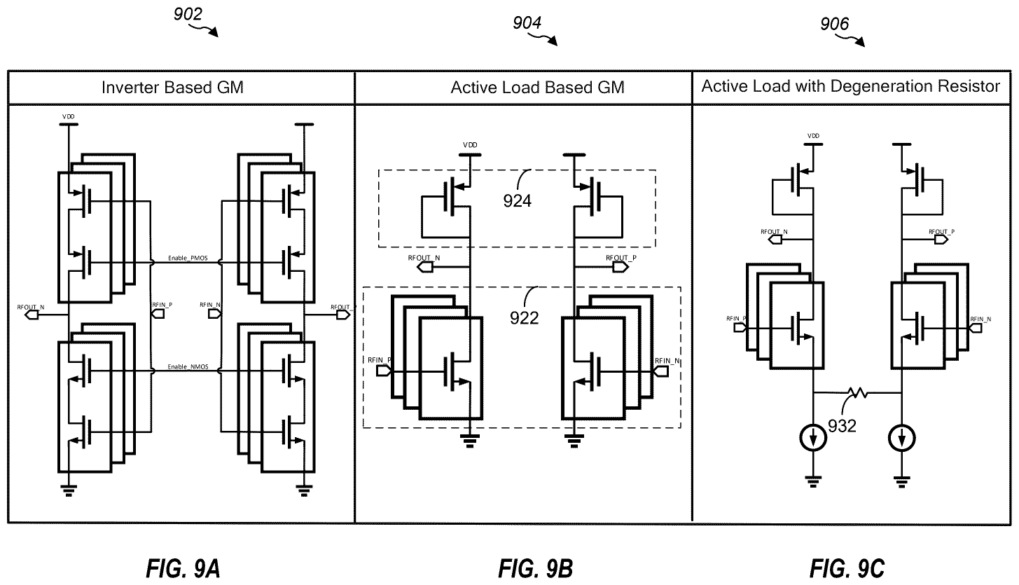

The second gain stage 614 includes second gain or amplification circuity configured to amplify a received amplified RF input signal 634 received from the first gain stage 612. The second gain stage 614 may include or correspond to transconductance (Gm) gain stage and configured to output a current proportional to its input voltage. For example, the second gain stage 614 may include a transconductance amplifier. As illustrated in the example of FIG. 6, the second gain stage 614 includes a fully-differential transconductance amplifier, having a differential set of inputs and outputs. In some implementations, the second gain stage 614 includes or corresponds to an inductor-less Gm stage. Examples of second gain or amplification circuity of the second gain stage 614 are further described with reference to FIGS. 9A-9C.

In some implementations, the two-stage LNA 602 includes a load or load stage, such as the load 516 of FIG. 5. The load or load stage may include or correspond to a load for the two-stage LNA 602, including the first gain stage 612 thereof. The load may include or correspond to an output tank and include circuity configured to generate a load for RF signal amplification. The load may include one or more inductors. In some implementations, the load may not include deQ resistors or one or more adjustable resistors, such as not include the adjustable resistors 552 and 554 of FIG. 5. An example a load of the two-stage LNA 602 is further described with reference to FIG. 7.

The feedforward stage 616 includes feedforward circuitry 618 and 620 in feedforward paths 622 and 624. The feedforward stage 616 is coupled to the first gain stage 612 and the mixer 604, and is coupled in parallel with the second gain stage 614. To illustrate, inputs into the feedforward paths 622 and 624 are coupled to outputs of the first gain stage 612 and inputs of the second gain stage 614, and outputs from the feedforward paths 622 and 624 are coupled to outputs of the second gain stage 614 and inputs of the mixer 604. The feedforward stage 616, and feedforward paths 622 and 624 thereof, operate as a feedforward stage, as opposed to a feedback stage, due to the high input impedance of the second gain stage 614 and low output impedance of the second gain stage 614 (e.g., close to zero or a virtual ground in some cases).

The feedforward stage 616 includes an alternative and optional path for current from the first gain stage 612 to be provided to the mixer 604 as compared to a second gain path through the second gain stage 614. In the example of FIG. 6, the feedforward stage 616 includes two alternative paths, feedforward paths 622 and 624, for the different portions of the RF input signal as the two-stage LNA 602 is operating in a differential mode with a corresponding pair of signal components.

The feedforward stage 616 may include or correspond to a passive feedforward stage with traces to provide an alternative path around the second gain stage 614 where the feedforward circuitry 618 and 620 only includes passive circuit components in some implementations. For example, each of the feedforward paths 622 and 624 (e.g., traces) include feedforward circuitry 618 and 620 of one or more fixed resistors, capacitors, and/or inductors. As one illustrative example, each of the feedforward circuitry 618 and 620 includes a single resistor. As another illustrative example, each of the feedforward circuitry 618 and 620 includes a resistor and a capacitor coupled in series.

In other implementations, the feedforward stage 616 may include or correspond to an active feedforward stage, and the feedforward circuitry 618 and 620 may include one or more active components, such as switches, transistors, adjustable resistors, networks of resistors, etc. For example, the feedforward stage 616 may include one or more transistors, such as a single p-type NMOS transistor, a single n-type NMOS transistor, or a p-type NMOS transistor and an n-type NMOS transistor coupled in series. The active components of the feedforward circuitry 618 and 620 may be controlled by a controller, such as the controller 340 of FIG. 3, or a separate dedicated controller, not shown in FIG. 6, of feedforward circuitry 618 and 620. The controller may be configured to adjust an impedance of the feedforward stage 616, such as impedances of the feedforward circuitry 618 and 620 and the feedforward paths 622 and 624. By adjusting the impedance of the feedforward stage 616, the controller may control the amount of current through the feedforward stage 616 and which is not amplified by the second gain stage 614 to better control the overall gain and linearity of the two-stage LNA 602. Additional examples of the feedforward stage 616, including the feedforward circuitry 618 and 620 thereof, of the two-stage LNA 602 are further described with reference to FIGS. 7 and 8.

As compared to the second gain stage 614, the feedforward stage 616 may not amplify its portion of the received current from the amplified RF input signal 634 received from the first gain stage 612. This may cause an output signal from the two-stage LNA 602 and mixer 604 to have a lower and more constant gain as compared to other two-stage LNAs, such as the two-stage LNA 502 of FIG. 5, which provide all of the current from a first gain stage to a second gain stage.

The mixer 604 may include or correspond to the mixer 332 of FIG. 3, the mixer 424 of FIG. 4, or the mixer 504 of FIG. 5. The mixer 604 may include or correspond to a frequency mixer or multiplier configured to generate a new signal, including or having one or more new frequencies, based on two signals applied to it, such as the difference of the frequencies of the two signals applied to it. For example, the mixer 604 is configured to generate an output based on an input signal and a local oscillator (LO) signal. In some implementations, the mixer 604 may include or correspond to a passive mixer. Additionally, the mixer 604 may be viewed as active or driven when combined with the second gain stage 614. The mixer 604 may include or correspond to an unbalanced mixer, a single-balanced mixer, or a double-balanced mixer. The mixer 604 may include one or more circuit components, such as transistors or diodes to generate the output. In certain implementations there may be components that can be included between the second gain stage 614 and the mixer 604 (e.g., buffers or the like that can be considered part of or separate from the mixer 604).

In FIG. 6, the mixer 604 is configured to receive an amplified RF input signal (which has potentially been twice amplified, once by each stage of the two-stage LNA 602) from the second gain stage 514 of the two-stage LNA 602 and to receive an LO signal from LO circuitry (not shown in FIG. 5), such as the LO generation circuitry of FIG. 4. The mixer 604 is configured to mix the received signals and generate a mixed signal based on the inputs, output signal 640. The output signal is provided to baseband processing circuitry, such as a baseband filter, not shown in FIG. 6 for simplicity. The baseband processing circuitry may include or correspond to BBF 334 as in FIG. 3 or the digital baseband processor 412 of FIG. 4. In some implementations, the baseband processing circuitry includes a transinductance amplifier (TIA) configured to amplify the output or baseband signal, such as to convert current to voltage.

In some implementations, the baseband processor includes a baseband filter or is configured to perform baseband filtering. In other implementations, the wireless receiver circuit 600 further includes a baseband filter separate from the baseband processor. The wireless receiver circuit 600 may also be coupled to an antenna, such as antenna 410 of FIG. 4, and configured to receive RF energy received by the antenna at the input of the first gain stage 612 of the two-stage LNA 602.

During operation, an RF signal is received by the antenna and provided to the receive chain of the wireless receiver circuit 600 illustrated in FIG. 6. To process the received RF signal at the mixer 604, the received RF signal may need to be amplified before being mixed and downconverted to baseband frequencies for processing by a baseband processor. The two-stage LNA 602 receives the RF input signal 632 at an input of the first gain stage 612, and the first gain stage 612 amplifies the RF input signal 632 to generate the amplified RF input signal 634.

The first gain stage 612 provides the amplified RF input signal 634 to the mixer 604 via the second gain stage 614, the feedforward stage 616, or both. At moderate or intermediate input powers, the first gain stage 612 provides the amplified RF input signal 634 to the mixer 604 via both the second gain stage 614 and the feedforward stage 616. To illustrate, a first portion of current of the amplified RF input signal 634 is provided to the second gain stage 614, where it is amplified, such as by a transconductance or Gm amplifier. A second portion of current of the amplified RF input signal 634 is provided to the feedforward stage 616, where it passes through the two feedforward paths 622 and 624 and the circuitry thereof unamplified. The feedforward circuitry 618 and 620 of the forward paths 622 and 624, such as the impedance thereof along with the power of the amplified RF input signal 634, may control how much current is provided to each of the alternative paths from the first gain stage 612 to the mixer 604. As the signal is differential in the example of FIG. 6, each alternative path to the mixer 604 has two signal portions and paths.

The amplified RF input signal 636 (twice amplified RF input signal) output from the second gain stage 614 is combined with the amplified RF input signal 634 (single amplified RF input signal) output from the feedforward stage 616 to generate the combined amplified RF input signal 638, and the combined amplified RF input signal 638 is provided to the mixer 604.

To process the received RF signal at the mixer 604, an LO signal is also generated and provided to the mixer 604 by LO circuitry, as known in the art. The mixer 604 processes (e.g., mixes) the two received signals to generate a processed, mixed or baseband signal, the output signal 640, for further/baseband processing by the baseband processor.

In some operational modes, such as at low input signal power modes, the amplified RF signal (e.g., combined amplified RF input signal 638 or the output signal 640) generated by the two-stage LNA 602 may satisfy certain operating constraints of networks, such as linearity, NF, IIP3, etc., and both stages are needed to meet gain or input power requirements.

In some operational modes, such as at high input signal power modes, the second gain stage 614 of the two-stage LNA 602 may not be needed or may cause non-linearity, and thus, the second gain stage 614, and optionally the feedforward stage 616, may be bypassed by bypass circuitry, such as described further with reference to FIG. 8. For example, the gain of the first gain stage 612 may be enough to generate the output signal 640 for baseband processing and/or the gain from the second gain stage 614 may cause the output signal 640 to have issues with meeting certain constraints of networks, such as linearity, NF, IIP3, etc.

As compared to the example of the two-stage LNA 502 of FIG. 5, the two-stage LNA 602 may have improved performance between high and low input powers, such as where the second gain stage 614 is not needed to amplify the RF signal and when the second gain stage 614 receives all or substantially all of the current from the first gain stage 612. This moderate/intermediate input signal power may include or correspond to RF input signal powers between −70 dBm to −20 dBm for some operating modes or operating frequencies, such as Wi-Fi 320 MHz.

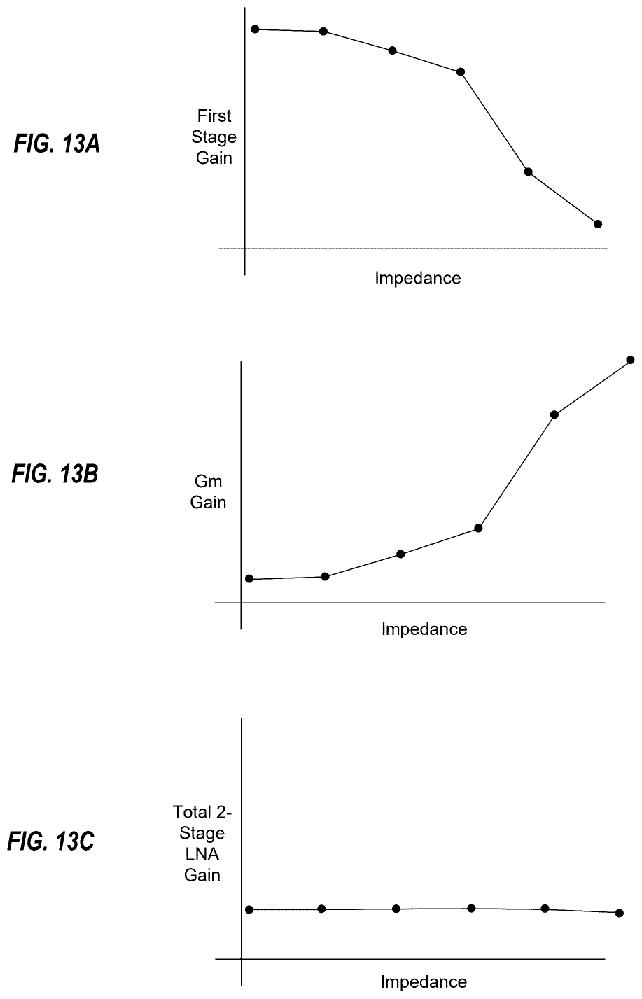

For example, during operations where gain/amplification from the second gain stage 614 may be required to meet certain gain or power requirements or design constraints for the wireless receiver circuit 500 at moderate or intermediate input powers, the total gain of the two-stage LNA 602 may be kept substantially constant and linear by providing a portion of the current from the first gain stage 612 to mixer 604 via the feedforward stage 616 independent of the second gain stage 614 and unamplified. As illustrated in FIGS. 13A-13C and described further with reference to FIGS. 13A-13C, the total gain of the two-stage LNA 602 may be kept substantially constant because the gain generated by the first and second stages has an inverse relationship. Because of this inverse relationship, the two-stage LNA 702 may have a substantially constant gain and linearity across different RF signal input powers. Accordingly, the two-stage LNA 602 improves linearity, NF, IIP3, and EVM and may meet challenging next generation design requirements for high bandwidth operational modes at moderate/intermediate input signal powers.

FIG. 7 is a circuit diagram illustrating a wireless receiver circuit 700 according to one or more aspects. The wireless receiver circuit 700 may include or correspond to a wireless receiver circuit for wideband Wi-Fi operations, such as HT 320 operations of Wi-Fi 7.

In some embodiments, the wireless receiver circuit 700 may be part of a sub-6 GHz radio frequency (RF) transceiver, a converged sub-6 GHz and mm Wave radio frequency (RF) transceiver, or a mmWave radio frequency (RF) transceiver. In some embodiments, portions of the RF receiver (or transceiver) of FIG. 7 may be located in a single integrated circuit (IC) sharing a common substrate, and each portion may be coupled to each other and to a PCB.

The wireless receiver circuit 700 includes or corresponds to a portion of a wireless receiver circuit, such as an LNA and a mixer of a particular receive chain of a wireless receiver. Similar to FIGS. 5 and 6, the wireless receiver circuit 700 of FIG. 7 may be coupled to a baseband filter and an antenna and configured to receive RF signals and transmit RF signals. In FIG. 7, one receive chain is illustrated for simplicity.

The wireless receiver circuit 700 includes a two-stage LNA 702 and a mixer 704. In FIG. 7, one exemplary receive chain is illustrated for simplicity. Each receive chain of the wireless receiver circuit 700 may include a two-stage LNA 702 and a mixer 704. The wireless receiver circuit 700 may include many more receive chains and groups of receive chains. For example, in a particular implementation, the wireless receiver circuit 700 may include 8 groups of 8 receive chains for a total of 64 receive chains. Each group of receive chains may include or correspond to a separate chip or a portion of a chip which is implemented on a PCB.

The two-stage LNA 702 may include or correspond to the amplifier 320 of FIG. 3, the amplifier 422 of FIG. 4, the two-stage LNA 502 of FIG. 5, or the two-stage LNA 602 of FIG. 6. The two-stage LNA 702 includes a first gain stage 712, a second gain stage 714, a load 716, and a feedforward stage 718. The two-stage LNA 702 is configured to receive an RF input signal 792, to amplify the RF input signal 792 to generate an amplified RF input signal 794, and to provide the amplified RF input signal 794 to the mixer 704 via the second gain stage 714, the feedforward stage 718, or both.

Depending on the input power of the RF input signal 792, and the corresponding power of the amplified RF input signal 794 from the first gain stage 712, the amplified RF input signal 794 from the first gain stage 712 may be routed or provided to the mixer 704 via the second gain stage 714 alone, the feedforward stage 718 alone, or both. For example, a portion (first portion) of the current of the amplified RF input signal 794 from the first gain stage 712 may be provided to the mixer 704 via the second gain stage 714, and a portion (second portion) of the current of the amplified RF input signal 794 from the first gain stage 712 may be provided to the mixer 704 via the feedforward stage 718 without second amplification. The portion (first portion) of the current of the amplified RF input signal 794 from the first gain stage 712 that is provided to the mixer 704 via the second gain stage 714 is amplified a second time by the second gain stage 714. Thus, the amplified RF input signal received by the mixer 704 may correspond to a combined amplified RF input signal 798 including current from a twice amplified RF input signal 796 from the second gain stage 714 and current from the amplified RF input signal 794 signal from the feedforward stage 718.

The first gain stage 712 is coupled to an RF input, to the second gain stage 714, to the load 716, and to the feedforward stage 718. The first gain stage 712 is coupled to the mixer 704 via the second gain stage 714 and the feedforward stage 718. For example, outputs (e.g., differential outputs) of the first gain stage 712 are coupled to inputs of the second gain stage 714 and to inputs of the feedforward stage 718.

The first gain stage 712 includes first gain or amplification circuity configured to amplify the RF input signal 792 received at the first gain stage 712 from an antenna via RFFE circuity. The first gain stage 712 may include or correspond to a cascode amplifier or cascade amplification circuitry including multiple transistors coupled in series (or a cascading fashion). The first gain stage 712 may include one or more other circuit components, such as one or more other passive circuit components such as inductors, capacitors, or resistors. The first gain stage 712 may include or correspond to a voltage gain stage and may be configured to operate in a voltage gain mode.

As illustrated in the example of FIG. 7, the first gain stage 712 includes a first transistor 722, a second transistor 724, a first inductor 726, a second inductor 728, a capacitor 734 and a resistor 732.

The first and second transistors 722 and 724 may include or correspond to cascode transistors and are coupled in series. As illustrated in the example of FIG. 7, the first and second transistors 722 and 724 are n-type MOSFETS (NMOS) coupled in series (e.g., drain to source) where a gate of the second transistor 724 is coupled to an RF input, via the first inductor 726 and configured to receive an RF input signal. The first transistor 722, such as a drain thereof, is coupled to an output of the load 716 and an input of the second gain stage 714.

The first inductor 726 is configured to receive the RF input signal 792 and provide the RF input signal 792 to the gate of the second transistor 724. The second inductor 726 is coupled to the second transistor 724, such as a source thereof, to circuit ground, and to capacitor 734. Capacitor 734 is coupled to resistor 732, and resistor 732 is coupled to one output of the load 716 and an input of the second gain stage 714.

The second gain stage 714 is coupled to first gain stage 712, the feedforward stage 718, and the mixer 704. For example, inputs (e.g., differential inputs) of the second gain stage 714 are coupled to outputs of the first gain stage 712 and to inputs of the feedforward stage 718, and outputs (e.g., differential outputs) of the second gain stage 714 are coupled to inputs of the mixer 704.

The second gain stage 714 includes second gain or amplification circuity configured to amplify a received amplified RF input signal 794 received from the first gain stage 712. The second gain stage 714 may include or correspond to transconductance (Gm) gain stage and configured to output a current proportional to its input voltage. For example, the second gain stage 714 may include a transconductance amplifier. As illustrated in the example of FIG. 7, the second gain stage 714 includes a fully-differential transconductance amplifier, having a differential set of inputs and outputs. In some implementations, the second gain stage 614 includes or corresponds to an inductor-less Gm stage. Examples of second gain or amplification circuity of the second gain stage 714 are further described with reference to FIGS. 9A-9C.

The load 716 includes or corresponds to a load for the two-stage LNA 702, including the first gain stage 712 thereof. The load 716 may include or correspond to an output tank and include circuity configured to generate a load for RF signal amplification. The load 716 includes one or more inductors. As compared to the load 516 of FIG. 5, the load 716 does not include one or more adjustable resistors or one or more deQ resistors, such as the first adjustable resistor 552 or the second adjustable resistor 554 of FIG. 5.

As illustrated in the example of FIG. 7, the load 716 includes a first inductor 742 and a second inductor 744. The inductors 742 and 744 are coupled in parallel with each other. Specifically, the inductors 742 and 744 are coupled with an opposing orientation (e.g., a subtractive mode coupled with their windings and respective inputs and outputs in opposite directions). To illustrate, the orientation of the inductors are opposed 742 and 744 with the first inductor 742 having an output towards the circuit source (upwards in FIG. 7) and the second inductor 744 having an output towards the first gain stage 712 and the circuit drain/ground (downwards in FIG. 7).

As compared to the two-stage LNA 502 of FIG. 5, the two-stage LNA 702, including the load 716, does not experience unwanted signal wasting through the load 716, such as through resistors thereof, even at moderate or intermediate input power signal operational modes. Accordingly, the efficiency and performance of the two-stage LNA 702 is improved over the two-stage LNA 502 of FIG. 5.

The feedforward stage 718 includes feedforward circuitry 719 and 720 in feedforward paths 752 and 754. The feedforward stage 718 may include or correspond to the feedforward stage 616 of FIG. 6. The feedforward circuitry 719 and 720 may include or correspond to the feedforward circuitry 618 and 620 of FIG. 6, and the feedforward paths 752 and 754 may include or correspond to the feedforward paths 622 and 624 of FIG. 6.

The feedforward stage 718 is coupled to the first gain stage 712 and the mixer 704, and the feedforward stage 718 is coupled in parallel with the second gain stage 714. To illustrate, inputs into the feedforward paths 752 and 754 are coupled to outputs of the first gain stage 712 and inputs of the second gain stage 714, and outputs from the feedforward paths 752 and 754 are coupled to outputs of the second gain stage 714 and inputs of the mixer 704. The feedforward stage 718, and feedforward paths 752 and 754 thereof, operate as a feedforward stage, as opposed to a feedback stage, due to the high input impedance of the second gain stage 714 and low output impedance of the second gain stage 714 (e.g., close to zero or a virtual ground in some cases).

The feedforward stage 718 includes an alternative and optional path for current from the first gain stage 712 to be provided to the mixer 704 as compared to a second gain path through the second gain stage 714. In the example of FIG. 7, the feedforward stage 718 includes two alternative paths, feedforward paths 752 and 754, for the different portions of the RF input signal as the two-stage LNA 702 is operating in a differential mode with a corresponding pair of signal components.

The feedforward stage 718 may include or correspond to a passive feedforward stage or an active feedforward stage, as described with reference to the feedforward stage 616 of FIG. 6. In the example of FIG. 7, the feedforward stage 718 is an active feedforward stage where each of the feedforward circuitry 719 and 720 include active components of an adjustable resistor 762 and a capacitor 764. The adjustable resistor 762 (e.g., a variable resistor) is coupled in series with the capacitor 764, and the adjustable resistor may be controlled by a controller, such as the controller 340 of FIG. 3, or a separate dedicated controller, not shown in FIG. 7. The controller may be configured to adjust an impedance of the feedforward stage 718, such as impedances of the feedforward circuitry 719 and 720 and the feedforward paths 752 and 754. By adjusting the impedance of the feedforward stage 718, the controller may control the amount of current through the feedforward stage 718 and which is not amplified by the second gain stage 714 to better control the overall gain and linearity of the two-stage LNA 702. By adjusting the resistance/impedance of the adjustable resistor 762, the controller can keep a gain and linearity of the two-stage LNA 702 substantially constant, as described with reference to FIGS. 13A-13C. Additional examples of the feedforward stage 718, including the feedforward circuitry 719 and 720 thereof, of the two-stage LNA 702 are further described with reference to FIG. 8.

As compared to the second gain stage 714, the feedforward stage 718 may not amplify its portion of the received current from the amplified RF input signal 794 received from the first gain stage 712. This may cause an output signal from the two-stage LNA 702 and mixer 704 to have a lower and more constant gain as compared to other two-stage LNAs, such as the two-stage LNA 502 of FIG. 5, which provide all of the current from a first gain stage to a second gain stage.

The mixer 704 may include or correspond to the mixer 332 of FIG. 3, the mixer 424 of FIG. 4, the mixer 504 of FIG. 5, or the mixer 604 of FIG. 6. The mixer 704 may include or correspond to a frequency mixer or multiplier configured to generate a new signal, including or having one or more new frequencies, based on two signals applied to it, such as the difference of the frequencies of the two signals applied to it. For example, the mixer 704 is configured to generate an output based on an input signal and a local oscillator (LO) signal. In some implementations, the mixer 704 may include or correspond to a passive mixer. Additionally, the mixer 704 may be viewed as active or driven when combined with the second gain stage 714. The mixer 704 may include or correspond to an unbalanced mixer, a single-balanced mixer, or a double-balanced mixer. The mixer 704 may include one or more circuit components, such as transistors or diodes to generate the output.

In FIG. 7, the mixer 704 is configured to receive an amplified RF input signal (which has been twice amplified, once by each stage of the two-stage LNA 702) from the second gain stage 714 of the two-stage LNA 702 and to receive an LO signal from LO circuitry (not shown in FIG. 7), such as the LO generation circuitry of FIG. 4. The mixer 704 is configured to mix the received signals and generate a mixed signal based on the inputs, output signal 799. The output signal 799 is provided to baseband processing circuitry, such as a baseband filter, not shown in FIG. 7 for simplicity. The baseband processing circuitry may include or correspond to BBF 334 as in FIG. 3 or the digital baseband processor 412 of FIG. 4. In some implementations, the baseband processing circuitry includes a transinductance amplifier (TIA) configured to amplify the output or baseband signal, such as to convert current to voltage.

In some implementations, the baseband processor includes a baseband filter or is configured to perform baseband filtering. In other implementations, the wireless receiver circuit 700 further includes a baseband filter separate from the baseband processor. The wireless receiver circuit 700 may also be coupled to an antenna, such as antenna 410 of FIG. 4, and configured to receive RF energy received by the antenna at the input of the first gain stage 712 of the two-stage LNA 702.

During operation, an RF signal is received by the antenna and provided to the receive chain of the wireless receiver circuit 700 illustrated in FIG. 7. To process the received RF signal at the mixer 704, the received RF signal may need to be amplified before being mixed and downconverted to baseband frequencies for processing by a baseband processor. The two-stage LNA 702 receives the RF input signal 792 at an input of the first gain stage 712, and the first gain stage 712 amplifies the RF input signal 792 to generate the amplified RF input signal 794. For example, the first gain stage 712 of the two-stage LNA 702 receives the RF input signal 792 at the gate of the second transistor 724 via the first inductor 726. The RF input signal 792 applied to the gate of the second transistor 724 controls the flow of current through the second transistor 724 based on a load generated by the load 716. The application of the RF input signal 792 to the gate of the second transistor 724 amplifies the RF input signal 792.

The first gain stage 712 provides the amplified RF input signal 794 to the mixer 704 via the second gain stage 714, the feedforward stage 718, or both. At moderate or intermediate input powers, the first gain stage 712 provides the amplified RF input signal 794 to the mixer 704 via both the second gain stage 714 and the feedforward stage 718. To illustrate, a first portion of current of the amplified RF input signal 794 is provided to the second gain stage 714, where it is amplified, such as by a transconductance or Gm amplifier. A second portion of current of the amplified RF input signal 794 is provided to the feedforward stage 718, where it passes through the two feedforward paths 752 and 754 and the feedforward circuitry 719 and 720 thereof unamplified. The feedforward circuitry 719 and 720 of the feedforward paths 752 and 754, such as the impedance thereof along with the power of the amplified RF input signal 794, may control how much current is provided to each of the alternative paths from the first gain stage 712 to the mixer 704. Additionally, the controller may adjust a variable resistance of the adjustable resistors 762 of the feedforward circuitry 719 and 720 to adjust an impedance of the feedforward paths 752 and 754 based on the input power of the RF input signal 792. Adjusting the impedance of the feedforward paths 752 and 754 enables the controller to keep the gain of the two-stage LNA 702 constant, along with the linearity and NF. As the signal is differential in the example of FIG. 7, each alternative path to the mixer 704 has two signal portions and paths.

The amplified RF input signal 796 (twice amplified RF signal) output from the second gain stage 714 is combined with the amplified RF input signal 794 (single amplified RF input signal) output from the feedforward stage 718 to generate the combined amplified RF input signal 798, and the combined amplified RF input signal 798 is provided to the mixer 704.

To process the received RF signal at the mixer 704, an LO signal is also generated and provided to the mixer 704 by LO circuitry, as known in the art. The mixer 704 processes (e.g., mixes) the two received signals to generate a processed, mixed or baseband signal, the output signal 799, for further/baseband processing by the baseband processor.

In some operational modes, such as at low input signal power modes, the amplified RF signal (e.g., combined amplified RF input signal 798 or the output signal 799) generated by the two-stage LNA 702 may satisfy certain operating constraints of networks, such as linearity, NF, IIP3, etc., and both stages are needed to meet gain or input power requirements.

In some operational modes, such as at high input signal power modes, the second gain stage 714 of the two-stage LNA 702 may not be needed or may cause non-linearity, and thus, the second gain stage 714, and optionally the feedforward stage 718, may be bypassed by bypass circuitry, such as described further with reference to FIG. 8. For example, the gain of the first gain stage 712 may be enough to generate the output signal 799 for baseband processing and/or the gain from the second gain stage 714 may cause the output signal 799 to have issues with meeting certain constraints of networks, such as linearity, NF, IIP3, etc.

As compared to the example the two-stage LNA 502 of FIG. 5, the two-stage LNA 702 may have improved performance between high and low input powers, such as where the second gain stage 714 is not needed to amplify the RF signal and when the second gain stage 714 receives all or substantially all of the current from the first gain stage 712. This moderate/intermediate input signal power may include or correspond to RF input signal powers between −70 dBm to −20 dBm for some operating modes or operating frequencies, such as Wi-Fi 320 MHZ.

For example, during operations where gain/amplification from the second gain stage 714 may be required to meet certain gain or power requirements or design constraints for the wireless receiver circuit 500 at moderate or intermediate input powers, the total gain of the two-stage LNA 702 may be kept substantially constant and linear by providing a portion of the current from the first gain stage 712 to mixer 704 via the feedforward stage 718 independent of the second gain stage 714 and unamplified. As illustrated in FIGS. 13A-13C and described further with reference to FIGS. 13A-13C, the total gain of the two-stage LNA 702 may be kept substantially constant because as the gain generated by the first and second stages has an inverse relationship. Because of this inverse relationship, the two-stage LNA 702 may have a substantially constant gain and linearity across different RF signal input powers. Accordingly, the two-stage LNA 702 improves linearity, NF, IIP3, and EVM and may meet challenging next generation design requirements for high bandwidth operational modes at moderate/intermediate input signal powers.

FIG. 8 is a circuit diagram illustrating a wireless receiver circuit 800 according to one or more aspects. The wireless receiver circuit 800 may include or correspond to a wireless receiver circuit for wideband Wi-Fi operations, such as HT 320 operations of Wi-Fi 7.

In some embodiments, the wireless receiver circuit 800 may be part of a sub-6 GHz radio frequency (RF) transceiver, a converged sub-6 GHz and mmWave radio frequency (RF) transceiver, or a mmWave radio frequency (RF) transceiver. In some embodiments, portions of the RF receiver (or transceiver) of FIG. 8 may be located in a single integrated circuit (IC) sharing a common substrate, and each portion may be coupled to each other and to a PCB.

The wireless receiver circuit 800 includes or corresponds to a portion of a wireless receiver circuit, such as an LNA and a mixer of a particular receive chain of a wireless receiver.

The wireless receiver circuit 800 includes a two-stage LNA 802 and a mixer 804. In FIG. 8, one exemplary receive chain is illustrated for simplicity. Each receive chain of the wireless receiver circuit 800 may include a two-stage LNA 802, a mixer 804, and a baseband filter 806. The wireless receiver circuit 800 may include many more receive chains and groups of receive chains. For example, in a particular implementation, the wireless receiver circuit 800 may include 8 groups of 8 receive chains for a total of 64 receive chains. Each group of receive chains may include or correspond to a separate chip or portion of chip which is implemented on a PCB.

The two-stage LNA 802 may include or correspond to the amplifier 320 of FIG. 3, the amplifier 422 of FIG. 4, the two-stage LNA 502 of FIG. 5, the two-stage LNA 602 of FIG. 6, or the two-stage LNA 702 of FIG. 7. The two-stage LNA 802 includes a first gain stage 812, a second gain stage 814, a feedforward stage 816, and a bypass stage 818. The two-stage LNA 802 is configured to receive an RF input signal, to amplify the RF input signal to generate an amplified RF input signal, and to provide the amplified RF input signal to the mixer 804 via the second gain stage 814, the feedforward stage 816, or both.

Depending on the input power of the RF input signal, and the corresponding power of the amplified RF input signal from the first gain stage 812, the amplified RF input signal from the first gain stage 812 may be routed or provided to the mixer 804 via the second gain stage 814 alone, the feedforward stage 816 alone, or both. For example, a portion (first portion) of the current of the amplified RF input signal from the first gain stage 812 may be provided to the mixer 804 via the second gain stage 814, and a portion (second portion) of the current of the amplified RF input signal from the first gain stage 812 may be provided to the mixer 804 via the feedforward stage 816 without second amplification. The portion (first portion) of the current of the amplified RF input signal from the first gain stage 812 that is provided to the mixer 804 via the second gain stage 814 is amplified a second time by the second gain stage 814. Thus, the amplified RF input signal received by the mixer 804 may correspond to a combined amplified RF input signal including current from a twice amplified RF input signal from the second gain stage 814 and current from the amplified RF input signal from the feedforward stage 816.

Additionally, depending on the input power of the RF input signal, the two-stage LNA 802 is configured to bypass the second gain stage 814 altogether and no portion of the current of the amplified RF input signal from the first gain stage 812 may be routed or provided to the mixer 804 via the second gain stage 814. Rather, the entirety of the current of the amplified RF input signal from the first gain stage 812 may be routed or provided to the mixer 804 via the bypass stage 818.

The first gain stage 812 is coupled to an RF input, to the second gain stage 814, and to the feedforward stage 816. The first gain stage 812 is coupled to the mixer 804 via the second gain stage 814 and the feedforward stage 816. For example, outputs (e.g., differential outputs) of the first gain stage 812 are coupled to inputs of the second gain stage 814 and to inputs of the feedforward stage 816.

The first gain stage 812 includes first gain or amplification circuity configured to amplify the RF input signal received at the first gain stage 812 from an antenna via RFFE circuity. The first gain stage 812 may include or correspond to a cascode amplifier or cascade amplification circuitry including multiple transistors coupled in series (or a cascading fashion). The first gain stage 812 may include one or more other circuit components, such as one or more other passive circuit components such as inductors, capacitors, or resistors. The first gain stage 812 may include or correspond to a voltage gain stage and may be configured to operate in a voltage gain mode. Additionally, the first gain stage 812 may include or correspond to a hybrid gain stage and may be configured to operate in a transconductance gain mode when the second gain stage 814 is bypassed. In some aspects, the first gain or amplification circuity of the first gain stage 812 corresponds to the first gain stage 712 of FIG. 7.

The second gain stage 814 is coupled to first gain stage 812, the feedforward stage 816, and the mixer 804. For example, inputs (e.g., differential inputs) of the second gain stage 814 are coupled to outputs of the first gain stage 812 and to inputs of the feedforward stage 816, and outputs (e.g., differential outputs) of the second gain stage 814 are coupled to inputs of the mixer 804.

The second gain stage 814 includes second gain or amplification circuity configured to amplify a received amplified RF input signal received from the first gain stage 812. The second gain stage 814 may include or correspond to transconductance (Gm) gain stage and configured to output a current proportional to its input voltage (e.g., voltage to current mode). For example, the second gain stage 814 may include a transconductance amplifier. As illustrated in the example of FIG. 8, the second gain stage 814 includes a fully-differential transconductance amplifier, having a differential set of inputs and outputs. In some implementations, the second gain stage 614 includes or corresponds to an inductor-less Gm stage. Examples of second gain or amplification circuity of the second gain stage 814 are further described with reference to FIGS. 9A-9C.

In some implementations, the two-stage LNA 802 includes a load or load stage, such as the load 716 of FIG. 7. The load or load stage may include or correspond to a load for the two-stage LNA 802, including the first gain stage 812 thereof. The load may include or correspond to an output tank and include circuity configured to generate a load for RF signal amplification. The load may include one or more inductors. In some implementations, the load may not include deQ resistors or one or more adjustable resistors, such as not include the adjustable resistors 552 and 554 of FIG. 5.

As compared to the two-stage LNA 502 of FIG. 5, the two-stage LNA 802, including the load, does not experience unwanted signal wasting through the load, such as through resistors thereof, even at moderate or intermediate input power signal operational modes, as described with reference to FIG. 7. Accordingly, the efficiency and performance of the two-stage LNA 802 is improved over the two-stage LNA 502 of FIG. 5.

The feedforward stage 816 includes feedforward circuitry 822 and 824 in feedforward paths 826 and 828. The feedforward stage 816 may include or correspond to the feedforward stage 616 of FIG. 6. The feedforward circuitry 822 and 824 may include or correspond to the feedforward circuitry 618 and 620 of FIG. 6 or the feedforward circuitry 719 and 720 of FIG. 7, and the feedforward paths 826 and 828 may include or correspond to the feedforward paths 622 and 624 of FIG. 6 or the feedforward paths 752 and 754 of FIG. 7.

The feedforward stage 816 is coupled to the first gain stage 812 and the mixer 804, and is coupled in parallel with the second gain stage 814. To illustrate, inputs into the feedforward paths 826 and 828 are coupled to outputs of the first gain stage 812 and inputs of the second gain stage 814, and outputs from the feedforward paths 826 and 828 are coupled to outputs of the second gain stage 814 and inputs of the mixer 804. The feedforward stage 816, and feedforward paths 826 and 828 thereof, operate as a feedforward stage, as opposed to a feedback stage, due to the high input impedance of the second gain stage 814 and low output impedance of the second gain stage 814 (e.g., close to zero or a virtual ground in some cases).

The feedforward stage 816 includes an alternative and optional path for current from the first gain stage 812 to be provided to the mixer 804 as compared to a second gain path through the second gain stage 814. In the example of FIG. 8, the feedforward stage 816 includes two alternative paths, feedforward paths 826 and 828, for the different portions of the RF input signal as the two-stage LNA 802 is operating in a differential mode with a corresponding pair of signal components.

The feedforward stage 816 may include or correspond to a passive feedforward stage, or an active feedforward stage as described with reference to the feedforward stage 616 of FIG. 6. In the example of FIG. 8, the feedforward stage 816 is an active feedforward stage where each of the feedforward circuitry 822 and 824 includes active components of adjustable impedance network. The adjustable impedance network may include or correspond to a switched resistor network, or a network of switched and resistors. In the example of FIG. 8, the adjustable impedance network includes a plurality of parallel paths (paths coupled in parallel), where each path includes a switch 842 and a resistor coupled in series. The parallel paths are coupled in series with a capacitor 846. The parallel paths may be activated or deactivated (connected and disconnected) to adjust a resistance and impedance of the adjustable impedance network even though the resistors each have a fixed resistance and impedance. Although the implementation of FIG. 8 illustrates an example, where each path includes one resistor, in other examples, a path may include no resistors, or two or more resistors coupled in series and/or parallel. Additionally, or alternatively, the resistance of the resistors on different paths may have different resistances to enable a wider range of selectable resistance/impedances.

For example, the adjustable impedance network may be controlled by a controller, such as the controller 340 of FIG. 3, or a separate dedicated controller, not shown in FIG. 8. The controller may be configured to adjust an impedance of the feedforward stage 816, such as impedances of the feedforward circuitry 822 and 824 and the feedforward paths 826 and 828. By adjusting the impedance of the feedforward stage 816, the controller may control the amount of current through the feedforward stage 816 and which is not amplified by the second gain stage 814 to better control the overall gain and linearity of the two-stage LNA 802. By adjusting the resistance/impedance of the adjustable impedance network, the controller can keep a gain and linearity of the two-stage LNA 802 substantially constant, as described with reference to FIGS. 13A-13C. Additional examples of the feedforward stage 816, including the feedforward circuitry 822 and 824 thereof, of the two-stage LNA 802 are further described with reference to FIG. 8.

As compared to the second gain stage 814, the feedforward stage 816 may not amplify its portion of the received current from the amplified RF input signal received from the first gain stage 812. This may cause an output signal from the two-stage LNA 802 and mixer 804 to have a lower and more constant gain as compared to other two-stage LNAs, such as the two-stage LNA 502 of FIG. 5, which provide all of the current from a first gain stage to a second gain stage.

The bypass stage 818 is coupled to first gain stage 812, the second gain stage 814, the feedforward stage 816, and the mixer 804. For example, inputs (e.g., inputs for the differential portions of the RF signal) of the bypass stage 818 are coupled to outputs of the first gain stage 812, to inputs of the second gain stage 814, and to inputs of the feedforward stage 816, and outputs (e.g., outputs for the differential portions of the RF signal) of the bypass stage 818 are coupled to the outputs of the second gain stage 814, to outputs of the feedforward stage 816, and to inputs of the mixer 804.

The bypass stage 818 includes bypass paths 832 and 834 and bypass circuitry. The bypass circuitry may include or correspond to a switch, such as switches 836 and 838 in FIG. 8, or a transistor, and the bypass paths 832 and 834 may include or correspond to traces which bypass the second gain stage 814 and can disconnect the second gain stage 814 from operation in the two-stage LNA 802. Disconnecting the second gain stage 814 may improve performance at high input signal powers. For example, disconnecting the second gain stage 814 improves linearity and NF of the signal received at the mixer 804 from the two-stage LNA 802 when only the gain of the first gain stage 812 is needed.

As illustrated in the example of FIG. 8, the bypass paths 832 and 834 and the feedforward paths 826 and 828 may share a common path or portion of a path. The bypass paths 832 and 834 may extend around the feedforward circuitry of the feedforward stage and paths.

The mixer 804 may include or correspond to the mixer 332 of FIG. 3, the mixer 424 of FIG. 4, the mixer 504 of FIG. 5, the mixer 604 of FIG. 6, or the mixer 704 of FIG. 7. The mixer 804 may include or correspond to a frequency mixer or multiplier configured to generate a new signal, including or having one or more new frequencies, based on two signals applied to it, such as the difference of the frequencies of the two signals applied to it. For example, the mixer 804 is configured to generate an output based on an input signal and a local oscillator (LO) signal. In some implementations, the mixer 804 may include or correspond to a passive mixer. Additionally, the mixer 804 may be viewed as active or driven when combined with the second gain stage 814. The mixer 804 may include or correspond to an unbalanced mixer, a single-balanced mixer, or a double-balanced mixer. The mixer 804 may include one or more circuit components, such as transistors or diodes to generate the output.

In FIG. 8, the mixer 804 is configured to receive an amplified RF input signal (which has been twice amplified, once by each stage of the two-stage LNA 802) from the second gain stage 814 of the two-stage LNA 802 and to receive an LO signal from LO circuitry (not shown in FIG. 8), such as the LO generation circuitry of FIG. 4. The mixer 804 is configured to mix the received signals and generate a mixed signal based on the inputs, output signal. The output signal is provided to baseband processing circuitry, such as the baseband filter 806. The baseband processing circuitry, and/or the baseband filter 806, may include or correspond to BBF 334 as in FIG. 3 or the digital baseband processor 412 of FIG. 4. In some implementations, the baseband processing circuitry includes a transinductance amplifier (TIA) configured to amplify the output or baseband signal, such as to convert current to voltage.

In some implementations, the baseband processor includes the baseband filter 806 and is configured to perform baseband filtering. In other implementations, the wireless receiver circuit 800 further includes a baseband processor separate from the baseband filter 806. The wireless receiver circuit 800 may also be coupled to an antenna, such as antenna 410 of FIG. 4, and configured to receive RF energy received by the antenna at the input of the first gain stage 812 of the two-stage LNA 802.

In some implementations, the two-stage LNA 802 further includes one or more capacitors. The one or more capacitors may include capacitors for different functions, such as bypass capacitors, coupling capacitors, blocking capacitors, etc. In the example of FIG. 8, the two-stage LNA 802 includes capacitors 862-868. The capacitors 862-868 may reduce noise and provide cleaner signals to the various stages.

During operation, an RF signal is received by the antenna and provided to the receive chain of the wireless receiver circuit 800 illustrated in FIG. 8. To process the received RF signal at the mixer 804, the received RF signal may need to be amplified before being mixed and downconverted to baseband frequencies for processing by a baseband processor. The two-stage LNA 802 receives the RF input signal at an input of the first gain stage 812, and the first gain stage 812 amplifies the RF input signal to generate the amplified RF input signal.

The first gain stage 812 provides the amplified RF input signal to the mixer 804 via the second gain stage 814, the feedforward stage 816, or both. At moderate or intermediate input powers, the first gain stage 812 provides the amplified RF input signal to the mixer 804 via both the second gain stage 814 and the feedforward stage 816. To illustrate, a first portion of current of the amplified RF input signal is provided to the second gain stage 814, where it is amplified, such as by a transconductance or Gm amplifier. A second portion of current of the amplified RF input signal is provided to the feedforward stage 816, where it passes through the two feedforward paths 826 and 828 and the feedforward circuitry 822 and 824 thereof unamplified. The feedforward circuitry 822 and 824 of the feedforward paths 826 and 828, such as the impedance thereof along with the power of the amplified RF input signal, may control how much current is provided to each of the alternative paths from the first gain stage 812 to the mixer 804. Additionally, the controller may adjust a variable resistance of the adjustable resistors 862 of the feedforward circuitry 822 and 824 to adjust an impedance of the feedforward paths 826 and 828 based on the input power of the RF input signal. Adjusting the impedance of the feedforward paths 826 and 828 enables the controller to keep the gain of the two-stage LNA 802 constant, along with the linearity and NF. As the signal is differential in the example of FIG. 8, each alternative path to the mixer 804 has two signal portions and paths.

The amplified RF signal (twice amplified RF signal) output from the second gain stage 814 is combined with the amplified RF signal (single amplified RF signal) output from the feedforward stage 816 to generate the combined amplified RF input signal, and the combined amplified RF input signal is provided to the mixer 804.

To process the received RF signal at the mixer 804, an LO signal is also generated and provided to the mixer 804 by LO circuitry, as known in the art. The mixer 804 processes (e.g., mixes) the two received signals to generate a processed, mixed or baseband signal, the output signal, for further/baseband processing by the baseband processor.

In some operational modes, such as at low input signal power modes, the amplified RF signal (e.g., combined amplified RF input signal or the output signal) generated by the two-stage LNA 802 may satisfy certain operating constraints of networks, such as linearity, NF, IIP3, etc., and both stages are needed to meet gain or input power requirements.

In some operational modes, such as at high input signal power modes, the second gain stage 814 of the two-stage LNA 802 may not be needed or may cause non-linearity, and thus, the second gain stage 814, and optionally the feedforward stage 816, may be bypassed by the bypass paths 832 and 834 using the bypass circuitry (e.g., switches 836). For example, the gain of the first gain stage 812 may be enough to generate the output signal for baseband processing and/or the gain from the second gain stage 814 may cause the output signal to have issues with meeting certain constraints of networks, such as linearity, NF, IIP3, etc.

As compared to the example the two-stage LNA 502 of FIG. 5, the two-stage LNA 802 may have improved performance between high and low input powers, such as where the second gain stage 814 is not needed to amplify the RF signal and when the second gain stage 814 receives all or substantially all of the current from the first gain stage 812. This moderate/intermediate input signal power may include or correspond to RF input signal powers between −70 dBm to −20 dBm for some operating modes or operating frequencies, such as Wi-Fi 320 MHZ.

For example, during operations where gain/amplification from the second gain stage 814 may be required to meet certain gain or power requirements or design constraints for the wireless receiver circuit 500 at moderate or intermediate input powers, the total gain of the two-stage LNA 802 may be kept substantially constant and linear by providing a portion of the current from the first gain stage 812 to mixer 804 via the feedforward stage 816 independent of the second gain stage 814 and unamplified. As illustrated in FIGS. 13A-13C and described further with reference to FIGS. 13A-13C, the total gain of the two-stage LNA 802 may be kept substantially constant because as the gain generated by the first and second stages has an inverse relationship. Because of this inverse relationship, the two-stage LNA 702 may have a substantially constant gain and linearity across different RF signal input powers. Accordingly, the two-stage LNA 802 improves linearity, NF, IIP3, and EVM and may meet challenging next generation design requirements for high bandwidth operational modes at moderate/intermediate input signal powers.

FIG. 9A-9C correspond to circuit diagrams of exemplary second gain stage circuitry. For example, 9A-9C each illustrate one example of a transconductance amplifier or stage of the two-stage LNAs described herein, such as the two-stage LNAs of FIGS. 4-8.

FIG. 9A corresponds to a circuit diagram illustrating an inverter based transconductance amplifier, first transconductance amplifier 902. The first transconductance amplifier 902 includes two corresponding pairs of transistors coupled in series for each signal portion of the received differential RF input signal. The corresponding pairs of transistors correspond to two p-type MOSFETs coupled in series and two n-type MOSFETs coupled in series. Gates of the upper p-type MOSFETs and of the lower n-type MOSFETs are coupled together and receive an RF input, and gates of the lower p-type MOSFETs and gates of the upper n-type MOSFETs receive respective enable signals, PMOS enable and NMOS enable.

FIG. 9B corresponds to a circuit diagram illustrating an active load based transconductance amplifier, second transconductance amplifier 904. As compared to the first transconductance amplifier 902 of example of FIG. 9A, the second transconductance amplifier 904 of FIG. 9B does not include an inverter configuration and instead includes and a single transistor amplifier arrangement 912 with an active load portion 914. Additionally, the second transconductance amplifier 904 of FIG. 9B is a relative simpler design in terms of setting a DC bias condition of amplifier. However, the second transconductance amplifier 904 of FIG. 9B has a lower output impedance based on the diode-connected configuration of the active load. The output impedance can be adjusted by the size of the active load.

FIG. 9C corresponds to a circuit diagram illustrating an active load based transconductance amplifier with degeneration resistor, third transconductance amplifier 906. As compared to the second transconductance amplifier 904 of example of FIG. 9B, the third transconductance amplifier 906 further includes a degeneration resistor 932. The degeneration resistor 932 is coupled to the differential portions of the third transconductance amplifier 906 and connects the differential portions to provide negative feedback, which decreases gain and improves linearity. The degeneration resistor 932 is coupled to the differential portions between the transconductance amplifier portions (transistors which receive the RF input signal) and the grounds of third transconductance amplifier 906.

Although fully differential (e.g., differential-input and differential-output) second gain stages and Gm stages are illustrated in the examples of FIGS. 5-9C, in other implementations the second gain stage or Gm stage may be a non-fully differential stage, such as a single-input and a single-output stage or a differential-input and a single-output stage. Additionally, although differential (e.g., differential-input and differential-output) first gain stages, feedforward stages, and bypass stages are illustrated in the examples of FIGS. 5-9C, in other implementations one or more of the first gain stages, the feedforward stages, or the bypass stages be a non-fully differential stage, such as a single-input and a single-output stage or a differential-input and a single-output stage.

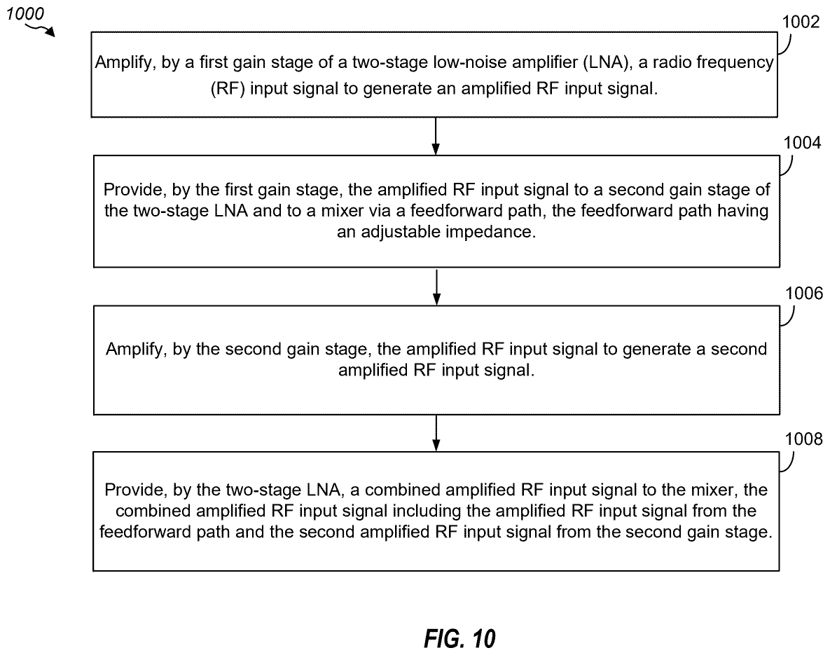

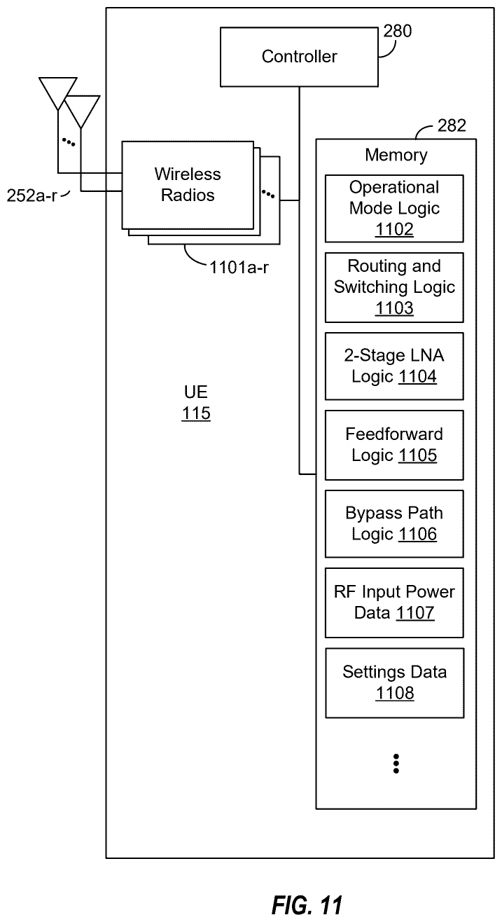

FIG. 10 is a flow diagram 1000 illustrating example blocks executed by a wireless communication device (e.g., a UE or base station) configured according to an aspect of the present disclosure. The example blocks will also be described with respect to UE 115 as illustrated in FIG. 11. FIG. 11 is a block diagram illustrating UE 115 configured according to one aspect of the present disclosure. UE 115 includes the structure, hardware, and components as illustrated for UE 115 of FIGS. 2-9. For example, UE 115 includes controller/processor 280, which operates to execute logic or computer instructions stored in memory 282, as well as controlling the components of UE 115 that provide the features and functionality of UE 115. UE 115, under control of controller/processor 280, transmits and receives signals via wireless radios 1101a-r and antennas 252a-r. Wireless radios 1101a-r includes various components and hardware, as illustrated in FIG. 2 for UE 115, including modulator/demodulators 254a-r, MIMO detector 256, receive processor 258, transmit processor 264, and TX MIMO processor 266. As illustrated in the example of FIG. 11, memory 282 stores operational mode logic 1102, routing and switching logic 1103, two-stage LNA logic 1104, feedforward logic 1105, bypass path logic 1106, RF input power data 1107, and settings data 1108. The data (1102-1108) stored in the memory 282 may include or correspond to data and/or logic to enable the operations described FIGS. 4-9.

For example, the operational mode logic 1102 may include or correspond to data for controlling different operating modes of the wireless device and the routing and switching logic 1103 may include or correspond to data for controlling the routing of RF input signals for different modes, such as different RF input power modes, different bandwidth or frequency modes (e.g., HT 320), etc. The two-stage LNA logic 1104 may include or correspond to data for controlling the operations of the two-stage LNA for different modes and/or RF input powers. The feedforward logic 1105 may include or correspond to data for controlling the operations of the feedforward stage of the two-stage LNA for different modes, such as controlling operations of the feedforward paths and/or the feedforward circuitry (e.g., the adjustable impedance circuitry). The feedforward logic 1105 may enable impedance selection of the adjustable impedance circuitry based on RF input power indicated by the RF input power data 1107. The bypass path logic 1106 may include or correspond to data for controlling the operations of the feedforward stage of the two-stage LNA for different modes, such as for different RF input powers indicated by the RF input power data 1107.

At block 1002, a wireless communication device, such as a UE or a base station, amplifies, by a first gain stage of a two-stage low-noise amplifier (LNA), a radio frequency (RF) input signal to generate an amplified RF input signal. The two-stage LNA may include to two-stage LNA as described with reference to FIGS. 4-8, such as amplifier 422, two-stage LNA 502 of FIG. 5, two-stage LNA 602 of FIG. 6, two-stage LNA 702 of FIG. 7, or two-stage LNA 802 of FIG. 8. The first gain stage may include or correspond a first gain stage of the above two-stage LNAs as described with reference to FIGS. 4-8, such as first gain stage 512 of FIG. 5, first gain stage 612 of FIG. 6, first gain stage 712 of FIG. 7, or first gain stage 812 of FIG. 8. The RF input signal may include or correspond to an input or unamplified RF input signal received at a first stage of a two-stage LNA as described with reference to FIGS. 4-8, such as RF input signal 632 of FIG. 6 or RF input signal 792 of FIG. 7. The amplified RF input signal may include or correspond to an amplified RF input signal generated by a first stage of a two-stage LNA as described with reference to FIGS. 4-8, such as amplified RF input signal 634 of FIG. 6 or amplified RF input signal 794 of FIG. 7. As one illustrative example, the first gain stage 612 of the two-stage LNA 602 receives the RF input signal 632 from an antenna and generates the amplified RF input signal 634 based on the RF input signal 632, as described with reference to FIG. 6. Many other examples are described in FIGS. 4-8.

At block 1004, the wireless communication device provides, by the first gain stage, the amplified RF input signal to a second gain stage of the two-stage LNA and to a mixer via a feedforward path, the feedforward path having an adjustable impedance. The second gain stage of the two-stage LNA may include or correspond to a second gain stage of the above two-stage LNAs as described with reference to FIGS. 4-8, such as second gain stage 514 of FIG. 5, second gain stage 614 of FIG. 6, second gain stage 714 of FIG. 7, or second gain stage 814 of FIG. 8. The mixer may include or correspond to a mixer as described with reference to FIGS. 4-8, such as mixer 424 of FIG. 4, mixer 504 of FIG. 5, mixer 604 of FIG. 6, mixer 704 of FIG. 7, or mixer 804 of FIG. 8. The feedforward path may include or correspond to a feedforward path of the feedforward paths and/or feedforward stage as described with reference to FIGS. 4-8, such as feedforward stage 616 of FIG. 6, feedforward stage 718 of FIG. 7, or feedforward stage 816 of FIG. 8. For example, the first gain stage 612 of the two-stage LNA 602 provides a first portion of the amplified RF input signal 634 to the second gain stage 614 and provides a second portion of the amplified RF input signal 634 to the mixer 604 via the feedforward stage 616, as described with reference to FIG. 6. Many other examples are described in FIGS. 4-8.

At block 1006, the amplify, by the second gain stage, the amplified RF input signal to generate a second amplified RF input signal. The second amplified RF input signal may include or correspond to a second or twice amplified RF input signal as described with reference to FIGS. 4-8, such as twice amplified RF input signal 636 of FIG. 6 or twice amplified RF input signal 796 of FIG. 7. As one illustrative example, the second gain stage 614 of the two-stage LNA 602 receives the amplified RF input signal 634 from the first gain stage 612 antenna and generates the twice amplified RF input signal 636 based on amplified RF input signal 634, as described with reference to FIG. 6. Many other examples are described in FIGS. 4-8.

At block 1008, the wireless communication device provides, by the two-stage LNA, a combined amplified RF input signal to the mixer, the combined amplified RF input signal including the amplified RF input signal from the feedforward path and the second amplified RF input signal from the second gain stage. The combined amplified RF input signal may include or correspond to a combined amplified RF input signal from the second gain stage and from the first gain stage via the feedforward stage as described with reference to FIGS. 4-8, such as combined amplified RF input signal 638 of FIG. 6 or combined amplified RF input signal 798 of FIG. 7. As one illustrative example, the two-stage LNA 602 provides the combined amplified RF input signal 638 to the mixer 604 by providing the twice amplified RF input signal 636 from the second gain stage 614 and by providing the amplified RF input signal 634 from the first gain stage 612 via the feedforward stage 616, as described with reference to FIG. 6. Many other examples are described in FIGS. 4-8. Because the feedforward stage 616 may provide a portion of the amplified RF input signal 634 from the first gain stage 612 to the mixer 604 amplified by the second gain stage 614 (e.g., not twice amplified) the overall linearity and NF of the two-stage LNA 602 may be improved and a gain of the two-stage LNA 602 may be substantial linear and constant for different input powers and/or impedances of the feedforward stage 616.

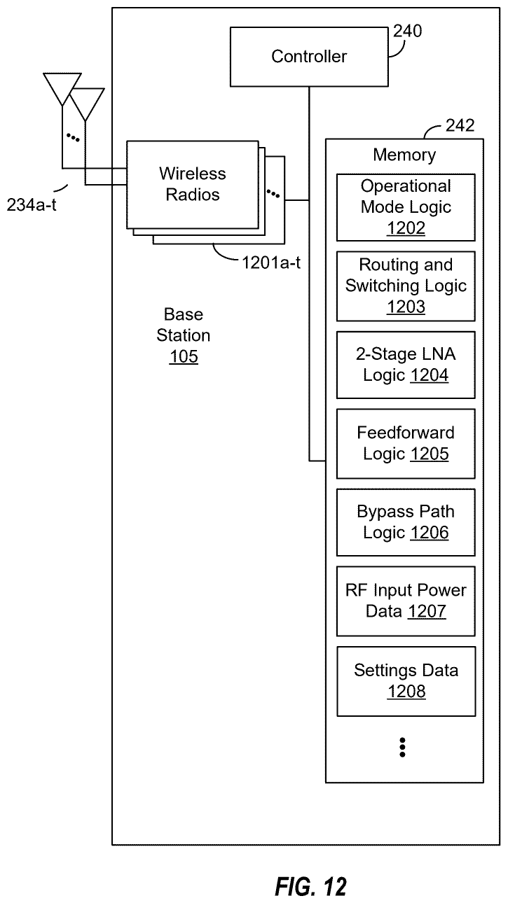

Although the operations of FIG. 10 may be directed to operation in a particular mode or with a particular input power (e.g., intermediate input powers for wideband modes), the two-stage LNA may operate in other manners for different operating modes and/or input powers. Additionally, or alternatively, although the operations of FIG. 10 were described with reference to UE 115 of FIG. 11, the operations of FIG. 10 may be performed by other wireless communication devices, such as network device (e.g., base station 105 of FIG. 12).

Referring to FIG. 12, FIG. 12 is a block diagram illustrating base station 105 configured according to one aspect of the present disclosure. Base station 105 includes the structure, hardware, and components as illustrated for base station 105 of any of FIGS. 2-9. For example, base station 105 includes controller/processor 240, which operates to execute logic or computer instructions stored in memory 242, as well as controlling the components of base station 105 that provide the features and functionality of base station 105. Base station 105, under control of controller/processor 240, transmits and receives signals via wireless radios 1201a-t and antennas 234a-t. Wireless radios 1201a-t includes various components and hardware, as illustrated in FIG. 2 for base station 105, including modulator/demodulators 232a-t, MIMO detector 236, receive processor 238, transmit processor 220, and TX MIMO processor 230. As illustrated in the example of FIG. 12, memory 242 stores operational mode logic 1202, routing and switching logic 1203, clock signal logic 1204, calibration logic 1205, LO cross route data 1206, calibration data 1207, and settings data 1208. The data (1202-1208) stored in the memory 242 may include or correspond to data and/or logic to enable the operations of FIGS. 4-9, and/or the data (1102-1108) of FIG. 11.

With reference to FIG. 10, the wireless communication devices described herein (e.g., UE 115 of FIG. 11 or base station 105 of FIG. 12) may execute additional blocks (or the wireless communication device may be configured further perform additional operations) in other implementations. For example, the wireless communication device may perform one or more operations described above, such as described with reference to FIGS. 4-8. As another example, the wireless communication device may perform one or more aspects as presented below after the description of FIGS. 13A-13C.

Accordingly, wireless communication devices may be able to more efficiently perform reception and transmission operations by utilizing enhanced two-stage LNAs with feedforward circuitry and may be able to operate with a single LNA in multiple operational modes, such as in advanced wideband modes of future wireless communication standards. Improved efficiency through enhanced and configurable components reduces overall power consumption and enables longer battery life. Accordingly, the device performance and experience may be increased due to the reduction in power usage.

FIGS. 13A-13C correspond to graphs of exemplary performance of the two-stage LNAs described herein. In FIGS. 13A-13C, gain is plotted on the x-axis (vertical axis) and resistance/impedance of the feedforward paths of the feedforward stage is plotted on the y-axis (horizontal axis). As depicted in FIGS. 13A-13C, resistance and impedance decreases from left to right with the far left portion indicating the most resistance, and gain increases from bottom to top with the uppermost portion indicating the most gain.

FIG. 13A corresponds to a graph illustrating first stage gain against resistance/impedance of the feedforward paths. In FIG. 13A, the first stage gain decreases with decreased resistance/impedance as shown by the downward sloping line from left to right.

FIG. 13B corresponds to a graph illustrating second stage gain against resistance/impedance of the feedforward paths. In FIG. 13B, the second stage gain increases with decreased resistance/impedance as shown by the upward sloping line from left to right. The second stage gain may include or correspond to total Gm stage gain in some implementations.

FIG. 13C corresponds to a graph illustrating total two-stage LNA gain against resistance/impedance of the feedforward paths. In FIG. 13C, the total two-stage LNA gain stays substantially constant with decreased resistance/impedance from left to right. The performance of the total two-stage LNA stays constant with changing resistance/impedance due to the inverse relationship between the first and second gain stage with respect to changes in resistance/impedance. Essentially, the decrease in first stage gain is offset by the increase in second stage gain. Accordingly, the linearity and NF of the two-stage LNA is improved as compared to two-stage LNAs without a feedforward stage. Because of the improved linearity and NF, the EVM performance of the two-stage LNA is also improved and may meet EVM specifications for future wideband modes, such as HT 320.

The adjustable resistance or current through the feedforward path enables the receiver to maintain a total gain of the two-stage amplifier linear, e.g., the total gain provided to the mixer. The first stage gain corresponds to the first stage output voltage over first stage input voltage, and the total GM gain (second/Gm stage gain plus feedforward current) corresponds to the total input current to mixer over the first stage output voltage. The equivalent GM gain corresponds to input current to mixer from Gm stage over the input voltage to Gm stage. To illustrate, as resistance of the feedforward path decreases, the first stage gain decreases due to the lower impedance of the feedforward path. However, as this resistance of the feedforward path decreases, the total Gm gain (including the feedforward path current) increases, as compared to higher feedforward path resistances, to maintain the total gain. Conversely, as the resistance of the feedforward path increases, the first stage gain increases due to the higher impedance of the feedforward path. However, as this resistance of the feedforward path increases, the total Gm gain decreases as less of the first stage's output current is being directed to the Gm stage and amplified by the Gm stage. Rather, a larger amount of the first stage's output current is being directed to go though the feedforward path and the Gm stage only amplifies the first stage output voltage. Accordingly, although the gain of the each of the first stage and Gm stages may be greatly affected by the adjustable resistance of and/or current through the feedforward path, the total gain of the two stages combined is constant and linear. Thus, the receiver front end gain stays relatively constant and the gain the mixer receives is relatively constant. Because the gain stays constant, the NF does not degrade, even for intermediate input powers. Additionally, the linearity, such as the input third-order intercept power (IIP3) value, improves because of the passive feedforward stage lowering the voltage swing in the receiver front end. In some implementations, the tunable impedance circuitry of the feedforward path has a tunable resistance range of 50 to 300 ohms.

In a first aspect, a receiver circuit includes: a two-stage low-noise amplifier (LNA) configured to amplify a radio frequency (RF) input signal and output a combined amplified RF input signal to a mixer, the two-stage LNA comprising: a first gain stage configured to amplify the RF input signal and output the amplified RF input signal to a second gain stage of the two-stage LNA and to the mixer via a feedforward path; and the second gain stage coupled to the first gain stage and configured to amplify the amplified RF input signal received from the first gain stage; feedforward circuitry in the feedforward path and coupled to the first gain stage and the mixer and coupled in parallel with the second gain stage, the feedforward circuitry configured to provide the amplified RF input signal from the first gain stage to the mixer, wherein the combined amplified RF input signal output by two-stage LNA includes the amplified RF input signal from the feedforward path and the amplified RF input signal from the second gain stage.

In a second aspect, alone or in combination with the first aspect, a first impedance at one or more inputs of the second gain stage is higher than a second impedance at one or more outputs of the second gain stage, wherein an impedance difference between the first impedance and the second impedance causes the feedforward path to provide at least a portion of the amplified RF signal to the mixer via the feedforward path.

In a third aspect, alone or in combination with one or more of the above aspects: a first portion of a current of the amplified RF input signal generated by the first gain stage is provided to the second gain stage via a second gain stage path, and a second portion of the current of the amplified RF input signal generated by the first gain stage is provided to the feedforward path.

In a fourth aspect, alone or in combination with one or more of the above aspects, the feedforward circuitry comprises adjustable impedance circuitry includes: an adjustable resistor and a capacitor coupled in series; a network of switchable resistors coupled in parallel and coupled to a capacitor in series; or one or more transistors coupled in series. In some such aspects, the one or more transistors coupled in series include a single p-type NMOS transistor, a single n-type NMOS transistor, or a p-type NMOS transistor and an n-type NMOS transistor coupled in series.

In a fifth aspect, alone or in combination with one or more of the above aspects, the feedforward circuitry comprises adjustable impedance circuitry, and the receiver circuit further including: a controller coupled to the adjustable impedance circuitry and configured to adjust an impedance of the adjustable impedance circuitry based on an input power of the RF input signal, wherein reducing the impedance of the adjustable impedance circuitry decreases first stage gain and increases second stage gain, and wherein increasing the impedance of the adjustable impedance circuitry increases first stage gain and decreases second stage gain to increase.

Additionally, or alternatively, reducing and increasing the impedance may have one or more other or additional results, such as 1) reducing the impedance of the adjustable impedance circuitry increases an amount of the current of the amplified RF input signal generated by the first gain stage that is provided to a second gain stage path, and increasing the impedance of the adjustable impedance circuitry decreases the amount of the current of the amplified RF input signal generated by the first gain stage that is provided to the second gain stage path; 2) reducing the impedance of the adjustable impedance circuitry increases an amount of the current of the amplified RF input signal generated by the first gain stage that is provided to the feedforward path, and increasing the impedance of the adjustable impedance circuitry decreases the amount of the current of the amplified RF input signal generated by the first gain stage that is provided to the feedforward path; and/or 3) reducing the impedance of the adjustable impedance circuitry causes more current to be provided to a second gain stage path, and increasing the impedance of the adjustable impedance circuitry causes more current to be provided to the feedforward path.

In a sixth aspect, alone or in combination with one or more of the above aspects, the feedforward circuitry comprises an adjustable impedance network further including: a controller coupled to the adjustable impedance network and configured to activate one or more switches of the adjustable impedance network to selectively couple one or more resistors of a network of switchable resistors in parallel to adjust an impedance of the adjustable impedance network based on an input power of the RF input signal.

In a seventh aspect, alone or in combination with one or more of the above aspects, the two-stage LNA comprises two feedforward paths including the feedforward path and a second feedforward path and corresponding to feedforward paths for differential portions of the amplified RF input signal, and wherein the two feedforward paths each include a plurality of selectable paths from the first gain stage to the mixer and which are alternative, non-amplifying paths as compared as to a path through the second gain stage, each path of the plurality including a resistor with a fixed resistance and a capacitor.

In an eighth aspect, alone or in combination with one or more of the above aspects, the first gain stage corresponds to a voltage gain stage, and wherein the second gain stage corresponds to a transconductance (Gm) gain stage.

In a ninth aspect, alone or in combination with one or more of the above aspects, the Gm stage includes an inverter based Gm stage, an active load based Gm stage, active load with degeneration resistors based Gm stage.

In a tenth aspect, alone or in combination with one or more of the above aspects, the first gain stage corresponds to a hybrid gain stage and is configured to operate in a voltage gain mode during low input power modes and configured to operate in to a transconductance (Gm) gain stage during high input power modes when the second gain stage and the feedforward path are bypassed.

In an eleventh aspect, alone or in combination with one or more of the above aspects, the first gain stage includes: an output tank coupled to a power supply and to the second gain stage, the output tank including two inductors coupled to each other in an opposing orientation; a pair of cascode transistors coupled to the output tank, the pair of cascode transistors coupled in series and configured to receive an RF input signal; an inductor coupled to ground and coupled to and in series with a transistor of the pair of cascode transistors; a capacitor coupled to the inductor and to the ground; and a resistor coupled to second gain stage and in series with the capacitor.

In a twelfth aspect, alone or in combination with one or more of the above aspects, the receiver circuit further includes: first and second bypass paths coupled to first gain stage and to the mixer, wherein each of the first and second bypass paths includes a switch and is configured to enable amplified RF input signals from the first gain stage to bypass the second gain stage in high input power operating modes.

In a thirteenth aspect, alone or in combination with one or more of the above aspects, the receiver circuit further includes: the mixer coupled to the second stage and the feedforward circuitry, the mixer configured to receive a local oscillator (LO) signal and to mix the combined amplified RF input signal with the LO signal to generate an output signal; and a baseband filter coupled to the mixer and configured to receive the output signal, wherein differential inputs of the baseband filter are coupled to differential outputs of the mixer, wherein the baseband filter includes a transimpedance amplifier separate from the two-stage LNA and configured to amplify the output signal.

In a fourteenth aspect, a method for wireless communication includes: amplifying, by a first gain stage of a two-stage low-noise amplifier (LNA), a radio frequency (RF) input signal to generate an amplified RF input signal; providing, by the first gain stage, the amplified RF input signal to a second gain stage of the two-stage LNA and to a mixer via a feedforward path, the feedforward path having an adjustable impedance; amplifying, by the second gain stage, the amplified RF input signal to generate a second amplified RF input signal; and providing, by the two-stage LNA, a combined amplified RF input signal to the mixer, the combined amplified RF input signal including the amplified RF input signal from the feedforward path and the second amplified RF input signal from the second gain stage.

In a fifteenth aspect, alone or in combination with the fourteenth aspect, the method further includes: setting, prior to providing the amplified RF input signal to the second gain stage and to the mixer via the feedforward path, an impedance of the adjustable impedance of the feedforward path based on an input power of the RF input signal; and mixing, by the mixer, the combined amplified RF input signal with a local oscillator (LO) signal to generate an output signal.

In a sixteenth aspect, alone or in combination with one or more of the fourteenth or fifteenth aspects, the method further includes, during a low input power mode or mode of operation: amplifying, by the first gain stage of a two-stage LNA, a second RF input signal to generate an amplified second RF input signal, the second RF input signal having a low input power and a second input power that is lower than a first input power of the RF input signal; providing, by the first gain stage, the amplified second RF input signal to a second gain stage of the two-stage LNA; amplifying, by the second gain stage, the amplified second RF input signal to generate a twice amplified second RF input signal; providing, by the second gain stage, the twice amplified second RF input signal to the mixer; and mixing, by the mixer, a twice amplified second RF input signal with a local oscillator (LO) signal to generate an output signal.

In a seventeenth aspect, alone or in combination with one or more of the fourteenth through sixteenth aspects, the method further includes during a high input power mode or mode of operation: amplifying, by the first gain stage of a two-stage LNA, a second RF input signal to generate an amplified second RF input signal, the second RF input signal having a high input power and a second input power that is higher than a first input power of the RF input signal; providing, by the first gain stage, the amplified second RF input signal to a mixer via first and second bypass paths and independent of the second gain stage and feedforward paths; and mixing, by a mixer, the amplified second RF input signal with a second LO signal to generate a second output signal.

In an eighteenth aspect, alone or in combination with one or more of the fourteenth through seventeenth aspects, the RF input signal correspond to an intermediate gain RF input signal and the two-stage LNA is operating in an intermediate input power mode.

In a nineteenth aspect, receiver circuitry includes: two-stage low-noise amplifier (LNA) circuitry including an input coupled to a radio frequency (RF) input and an output coupled to a mixer, the two-stage LNA comprising: first gain stage circuitry including an input coupled to the RF input; second gain stage circuitry coupled to the first gain stage circuitry; and an alternative path coupled to an input of the mixer and to an output of the first gain stage circuitry, the alternative path including adjustable impedance circuitry, wherein the alternative path provides a path to the input of the mixer from the output of the first gain stage circuitry independent of the second gain stage circuitry, wherein the output of the second gain stage circuitry and the output of the alternative path are coupled to the input of the mixer.

In a twentieth aspect, alone or in combination with the nineteenth aspect, the adjustable impedance circuitry comprises: an adjustable resistor and a capacitor coupled in series; a network of switchable resistors coupled in parallel and coupled to a capacitor in series; or one or more transistors coupled in series. In some such aspects, the one or more transistors coupled in series include a single p-type NMOS transistor, a single n-type NMOS transistor, or a p-type NMOS transistor and an n-type NMOS transistor coupled in series.

In a twenty-first aspect, alone or in combination with one or more of the above aspects, receiver circuity includes: two-stage low-noise amplifier (LNA) circuitry including an input coupled to a radio frequency (RF) input and an output coupled to a mixer, the two-stage LNA comprising: first gain stage circuitry including an input coupled to the RF input; second gain stage circuitry coupled to the first gain stage circuitry, wherein the second gain stage circuitry has a fully-differential configuration, and wherein differential inputs of the second gain stage circuitry are coupled to corresponding differential outputs of the first gain stage circuitry; and first and second alternative paths coupled to inputs of the mixer and to the outputs of the first gain stage circuitry, each alternative path including adjustable impedance circuitry, wherein each alternative path of the alternative paths provides a path to a corresponding input of the inputs of the mixer from a corresponding output of the outputs of the first gain stage circuitry independent of the second gain stage circuitry, wherein the outputs of the second gain stage circuitry and the outputs of the first and second alternative paths are coupled to the inputs of the mixer.

In a twenty-second aspect, alone or in combination with one or more of the above aspects, the second gain stage or circuitry corresponds to an operational transconductance amplifier (OTA) and is configured to output a current proportional to its input voltage.

In a twenty-third aspect, alone or in combination with one or more of the above aspects, a gain and a linearity of the two-stage LNA is substantially constant in low, moderate, and high input power modes.

In a twenty-fourth aspect, alone or in combination with one or more of the above aspects, the second stage or GM stage includes an inductor-less GM stage.

In a twenty-fifth aspect, alone or in combination with one or more of the above aspects, the two-stage LNA includes differential feedforward paths, including the feedforward path, for the second gain stage including one or more traces and one or more switches, wherein controller is configured to control a state of the one or more switches of the differential feedforward paths based on input power of the RF input signal to select a particular impedance from a set of configured impedances.

In a twenty-sixth aspect, alone or in combination with one or more of the above aspects, the two-stage LNA includes differential bypass paths for the second gain stage including one or more traces and one or more switches, wherein controller is configured to control a state of the one or more switches of the differential bypass paths based on input power of the RF input signal to bypass the second gain stage and/or the feedforward stage in high input power modes.

In a twenty-seventh aspect, alone or in combination with one or more of the above aspects, the second gain stage circuitry has a fully-differential configuration, and differential inputs of the second gain stage circuitry are coupled to corresponding differential outputs of the first gain stage circuitry.

In a twenty-eighth aspect, alone or in combination with one or more of the above aspects, the two-stage LNA, such as one or more stages thereof, is a non-fully differential amplifier, such as a single input and single output amplifier or a single input and dual output amplifier.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to FIGS. 1-13 include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art that one or more blocks (or operations) described with reference to FIGS. 3 and 4 may be combined with one or more blocks (or operations) described with reference to another of the figures. For example, one or more blocks (or operations) of FIG. 3 may be combined with one or more blocks (or operations) of FIG. 1. As another example, one or more blocks associated with FIG. 4 may be combined with one or more blocks (or operations) associated with FIGS. 1. Additionally, or alternatively, one or more operations described above with reference to FIGS. 1-4 may be combined with one or more operations described with reference to FIGS. 5-13

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single-or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or, any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, opposing terms such as “upper” and “lower” or “front” and back” or “top” and “bottom” or “forward” and “backward” are sometimes used for case of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A receiver circuit, comprising:
a two-stage low-noise amplifier (LNA) configured to amplify a radio frequency (RF) input signal and output a combined amplified RF input signal to a mixer, the two-stage LNA comprising:
a first gain stage configured to amplify the RF input signal and output the amplified RF input signal to a second gain stage of the two-stage LNA and to the mixer via a feedforward path;
the second gain stage coupled to the first gain stage and configured to amplify the amplified RF input signal received from the first gain stage; and
feedforward circuitry in the feedforward path and coupled to the first gain stage and the mixer and coupled in parallel with the second gain stage, the feedforward circuitry configured to provide the amplified RF input signal from the first gain stage to the mixer, wherein the combined amplified RF input signal output by two-stage LNA includes the amplified RF input signal from the feedforward path and the amplified RF input signal from the second gain stage.

2. The receiver circuit of claim 1, wherein a first impedance at one or more inputs of the second gain stage is higher than a second impedance at one or more outputs of the second gain stage, wherein an impedance difference between the first impedance and the second impedance causes the feedforward path to provide at least a portion of the amplified RF signal to the mixer via the feedforward path.

3. The receiver circuit of claim 1, wherein:
a first portion of a current of the amplified RF input signal generated by the first gain stage is provided to the second gain stage via a second gain stage path, and
a second portion of the current of the amplified RF input signal generated by the first gain stage is provided to the feedforward path.

4. The receiver circuit of claim 1, wherein the feedforward circuitry comprises adjustable impedance circuitry including:
an adjustable resistor and a capacitor coupled in series;
a network of switchable resistors coupled in parallel and coupled to a capacitor in series; or
one or more transistors coupled in series.

5. The receiver circuit of claim 1, wherein the feedforward circuitry comprises adjustable impedance circuitry, the receiver circuit further comprising:
a controller coupled to the adjustable impedance circuitry and configured to adjust an impedance of the adjustable impedance circuitry based on an input power of the RF input signal, wherein reducing the impedance of the adjustable impedance circuitry decreases first stage gain and increases second stage gain, and wherein increasing the impedance of the adjustable impedance circuitry increases first stage gain and decreases second stage gain to increase.

6. The receiver circuit of claim 1, wherein the feedforward circuitry comprises an adjustable impedance network further comprising:
a controller coupled to the adjustable impedance network and configured to activate one or more switches of the adjustable impedance network to selectively couple one or more resistors of a network of switchable resistors in parallel to adjust an impedance of the adjustable impedance network based on an input power of the RF input signal.

7. The receiver circuit of claim 1, wherein the two-stage LNA comprises two feedforward paths including the feedforward path and a second feedforward path and corresponding to feedforward paths for differential portions of the amplified RF input signal, and wherein the two feedforward paths each include a plurality of selectable paths from the first gain stage to the mixer and which are alternative, non-amplifying paths as compared as to a path through the second gain stage, each path of the plurality including a resistor with a fixed resistance and a capacitor.

8. The receiver circuit of claim 1, wherein the first gain stage corresponds to a voltage gain stage, and wherein the second gain stage corresponds to a transconductance (Gm) gain stage.

9. The receiver circuit of claim 8, wherein the Gm gain stage includes an inverter based Gm stage, an active load based Gm stage, active load with degeneration resistors based Gm stage.

10. The receiver circuit of claim 1, wherein the first gain stage corresponds to a hybrid gain stage and is configured to operate in a voltage gain mode during low input power modes and configured to operate in to a transconductance (Gm) gain stage during high input power modes when the second gain stage and the feedforward path are bypassed.

11. The receiver circuit of claim 1, wherein the first gain stage includes:
an output tank coupled to a power supply and to the second gain stage, the output tank including two inductors coupled to each other in an opposing orientation;
a pair of cascode transistors coupled to the output tank, the pair of cascode transistors coupled in series and configured to receive an RF input signal;
an inductor coupled to ground and coupled to and in series with a transistor of the pair of cascode transistors;
a capacitor coupled to the inductor and to ground; and
a resistor coupled to second gain stage and in series with the capacitor.

12. The receiver circuit of claim 1, further comprising:
first and second bypass paths coupled to first gain stage and to the mixer, wherein each of the first and second bypass paths includes a switch and is configured to enable amplified RF input signals from the first gain stage to bypass the second gain stage in high input power operating modes.

13. The receiver circuit of claim 1, further comprising:
the mixer coupled to the second gain stage and the feedforward circuitry, the mixer configured to receive a local oscillator (LO) signal and to mix the combined amplified RF input signal with the LO signal to generate an output signal; and
a baseband filter coupled to the mixer and configured to receive the output signal, wherein differential inputs of the baseband filter are coupled to differential outputs of the mixer, wherein the baseband filter includes a transimpedance amplifier separate from the two-stage LNA and configured to amplify the output signal.

14. A method for wireless communication, comprising:
amplifying, by a first gain stage of a two-stage low-noise amplifier (LNA), a radio frequency (RF) input signal to generate an amplified RF input signal;
providing, by the first gain stage, the amplified RF input signal to a second gain stage of the two-stage LNA and to a mixer via a feedforward path, the feedforward path having an adjustable impedance;
amplifying, by the second gain stage, the amplified RF input signal to generate a second amplified RF input signal; and
providing, by the two-stage LNA, a combined amplified RF input signal to the mixer, the combined amplified RF input signal including the amplified RF input signal from the feedforward path and the second amplified RF input signal from the second gain stage.

15. The method of claim 14, further comprising:
setting, prior to providing the amplified RF input signal to the second gain stage and to the mixer via the feedforward path, an impedance of the adjustable impedance of the feedforward path based on an input power of the RF input signal; and
mixing, by the mixer, the combined amplified RF input signal with a local oscillator (LO) signal to generate an output signal.

16. The method of claim 14, wherein during a low input power mode or mode of operation:
amplifying, by the first gain stage of a two-stage LNA, a second RF input signal to generate an amplified second RF input signal, the second RF input signal having a low input power and a second input power that is lower than a first input power of the RF input signal;
providing, by the first gain stage, the amplified second RF input signal to a second gain stage of the two-stage LNA;
amplifying, by the second gain stage, the amplified second RF input signal to generate a twice amplified second RF input signal;
providing, by the second gain stage, the twice amplified second RF input signal to the mixer; and
mixing, by the mixer, a twice amplified second RF input signal with a local oscillator (LO) signal to generate an output signal.

17. The method of claim 14, wherein during a high input power mode or mode of operation:
amplifying, by the first gain stage of a two-stage LNA, a second RF input signal to generate an amplified second RF input signal, the second RF input signal having a high input power and a second input power that is higher than a first input power of the RF input signal;
providing, by the first gain stage, the amplified second RF input signal to a mixer via first and second bypass paths and independent of the second gain stage and feedforward paths; and
mixing, by a mixer, the amplified second RF input signal with a second LO signal to generate a second output signal.

18. The method of claim 14, wherein the RF input signal correspond to an intermediate gain RF input signal and the two-stage LNA is operating in an intermediate input power mode.

19. Receiver circuitry, comprising:
two-stage low-noise amplifier (LNA) circuitry including an input coupled to a radio frequency (RF) input and an output coupled to a mixer, the two-stage LNA comprising:
first gain stage circuitry including an input coupled to the RF input;
second gain stage circuitry coupled to the first gain stage circuitry; and
an alternative path coupled to an input of the mixer and to an output of the first gain stage circuitry, the alternative path including adjustable impedance circuitry, wherein the alternative path provides a path to the input of the mixer from the output of the first gain stage circuitry independent of the second gain stage circuitry, wherein the output of the second gain stage circuitry and the output of the alternative path are coupled to the input of the mixer.

20. The receiver circuitry of claim 19, wherein the adjustable impedance circuitry comprises:
an adjustable resistor and a capacitor coupled in series:
a network of switchable resistors coupled in parallel and coupled to a capacitor in series; or
one or more transistors coupled in series.
